(19) United States
(12) Patent Application Publication
(10) Pub. No.: US 2025/0210508 A1
(43) Pub. Date: Jun. 26, 2025

(54) INTERCONNECT STRUCTURE WITH CAPACITOR AND METHODS FOR MAKING

(71) Applicant: Taiwan Semiconductor Manufacturing Company, LTD., Hsinchu (TW)

(72) Inventors: Ke-Jing Yu, Kaohsiung (TW); Anhao Cheng, Taichung (TW); Yen-Liang Lin, Tainan (TW); Ru-Shang Hsiao, Hsinchu (TW)

(21) Appl. No.: 18/392,242

(22) Filed: Dec. 21, 2023

(51) Int. Cl. H01L 23/522; H01L 23/58; H01L 27/146

(52) U.S. Cl. CPC H01L 23/5223; H01L 23/585; H10D 1/042; H10D 1/043; H10D 1/714; H10D 1/716; H10F 39/809

(57) ABSTRACT

Interconnect structures can include a capacitor of specified structure and/or a guard ring which surrounds a capacitor. The capacitor may include a bowed region with an expanded width that permits the inclusion of a void containing air or another gas. Alternatively, the capacitor may be an MIM capacitor or an MIMIM capacitor having a vertical trench and horizontal plates and formed from conformal layers. The guard ring reduces noise which may damage the capacitor. Any combination of these three features may be used to improve capacitance and reliability.

### BACKGROUND

Semiconductor packages containing integrated circuits are becoming Increasingly complex. For example, System on Integrated Chip (SolC) has been developed to include a plurality of device dies such as processors and memory cubes which are stacked vertically and interconnected. The device dies can be formed using different technologies and have different functions, and can be heterogeneously combined to obtain desired functionality, thus forming a system which is combined in one chip carrier package. This reduces manufacturing costs and optimizes device performance. Similar three-dimensional packages include System in Package (SiP), Wafer Level Package (WLP), and Package on Package (PoP).

Integrated circuits are formed on a semiconductor wafer. Photolithographic patterning processes use ultraviolet light to transfer a desired mask pattern to a photoresist on a semiconductor wafer. Etching processes may then be used to transfer to the pattern to a layer below the photoresist. This process is repeated multiple times with different patterns to build different layers on the wafer substrate and make a useful device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-axis cross-sectional view of a semiconductor package with an interconnect structure, in accordance with some embodiments. The interconnect structure includes a capacitor having a bowed region, and also includes a guard ring that surrounds the capacitor.

FIG. 1B is a plan view of the capacitor and the guard ring.

FIG. 1C is a magnified Y-axis cross-sectional view of the capacitor.

FIG. 2 is a first method for making an interconnect structure, along with the capacitor and the guard ring, in accordance with some embodiments.

FIG. 3A is a Y-axis cross-sectional view of the interconnect structure prior to beginning the method of FIG. 2.

FIG. 3B is a Y-axis cross-sectional view of the interconnect structure after applying an etch stop layer.

FIG. 3C is a Y-axis cross-sectional view of the interconnect structure after applying a dielectric layer over the etch stop layer.

FIG. 3D is a Y-axis cross-sectional view of the interconnect structure after doping the dielectric material to form a doped dielectric region,

FIG. 3E is a Y-axis cross-sectional view of the interconnect structure after a photoresist layer has been applied.

FIG. 3F is a Y-axis cross-sectional view of the interconnect structure after a trench for the capacitor has been etched into the dielectric material and through the doped dielectric region. The resulting trench has a bowed region.

FIG. 3G is a Y-axis cross-sectional view of the interconnect structure after a first metal has been deposited.

FIG. 3H is a Y-axis cross-sectional view of the interconnect structure after a first insulator has been deposited.

FIG. 3I is a Y-axis cross-sectional view of the interconnect structure after a second metal has been deposited. As illustrated here, the second metal fills the gap at the top of the trench, creating a void within the trench. The void can be considered a second insulator.

FIG. 3J is a Y-axis cross-sectional view of the interconnect structure after planarization of the surface of the dielectric material.

FIG. 3K is a Y-axis cross-sectional view of the interconnect structure after the first insulator has been applied again. This isolates the second metal in the trench,

FIG. 3L is a Y-axis cross-sectional view of the interconnect structure after a third metal layer has been deposited.

FIG. 3M is a Y-axis cross-sectional view of the interconnect structure after patterning to form horizontal plates of the capacitor, and after application of a capping layer.

FIG. 3N is a Y-axis cross-sectional view of the interconnect structure after additional material is deposited to cover the capacitor.

FIG. 3O is a Y-axis cross-sectional view of the interconnect structure after addition of further etch stop layers and interconnect layers.

FIG. 3P is a Y-axis cross-sectional view of the interconnect structure after etching to form top via openings.

FIG. 4A is a plan view of one arrangement of the trench and horizontal plates of the capacitor, FIG. 4B is a perspective view of the capacitor of FIG. 4A.

FIGS. 4C-4J are various plan views of the capacitor in accordance with some embodiments, showing different shapes and arrangements of the trench and horizontal plates of the capacitor.

FIG. 5 is a Y-axis cross-sectional view illustrating one variation of the capacitor, where the aspect ratio of the capacitor (trench depth to plate width) is higher than the capacitor of FIG. 1A.

FIG. 6A and FIG. 6B are cross-sectional views illustrating additional variations of the capacitor, where the bowed region of the capacitor is located at a different depth in the trench of the capacitor.

FIG. 7A and FIG. 7B together illustrate a second method for making an interconnect structure, in accordance with some embodiments. Here, a second insulator is included in the trench.

FIG. 8A is a Y-axis cross-sectional view of the interconnect structure after the second metal has been deposited. As illustrated here, the second metal does not fill the gap at the top of the trench.

FIG. 8B is a Y-axis cross-sectional view of the interconnect structure after the second insulator has been deposited into the trench.

FIG. 8C is a Y-axis cross-sectional view of the interconnect structure after planarization.

FIG. 8D is a Y-axis cross-sectional view of the interconnect structure after etching of the second insulator to form a recess.

FIG. 8E is a Y-axis cross-sectional view of the interconnect structure after the recess has been filled with the second metal.

FIG. 9 is a third method for making an interconnect structure, in accordance with some embodiments. The capacitor has a different structure.

FIG. 10A is a Y-axis cross-sectional view of the interconnect structure after the second metal has been deposited and patterning to form horizontal plates of the capacitor.

FIG. 10B is a Y-axis cross-sectional view of the interconnect structure after application of a capping layer upon the capacitor.

FIG. 10C is a Y-axis cross-sectional view of the final interconnect structure after addition of further interconnect layers and formation of top vias.

FIG. 10D is a Y-axis cross-sectional view of a variation of the capacitor, where no bowed region is present in the capacitor.

FIG. 11 is a fourth method for making an interconnect structure, in accordance with some embodiments. The capacitor has an MIMIM structure formed from five conformal layers.

FIG. 12A is a Y-axis cross-sectional view of the interconnect structure after a trench for the capacitor has been formed in the dielectric material.

FIG. 12B is a Y-axis cross-sectional view of the interconnect structure after five conformal layers (MIMIM) have been deposited into the trench and upon the dielectric material.

FIG. 12C is a Y-axis cross-sectional view of the interconnect structure after patterning to obtain a stepped profile that exposes all three metal layers of the capacitor.

FIG. 12D is a Y-axis cross-sectional view of the interconnect structure after application of a capping layer upon the capacitor.

FIG. 12E is a Y-axis cross-sectional view of the final interconnect structure after addition of further interconnect layers and formation of top vias.

FIG. 12F is a Y-axis cross-sectional view of a variation of the MIMIM capacitor, where a bowed region is present in the capacitor.

FIG. 13A is a plan view of one arrangement of the trench and horizontal plates of the capacitor. FIG. 13B is a perspective view of the capacitor of FIG. 13A.

FIGS. 13C-13J are various plan views of the capacitor in accordance with some embodiments, showing different shapes and arrangements of the trench and horizontal plates of the capacitor.

FIG. 14 is a fifth method for making an interconnect structure, in accordance with some embodiments. The capacitor has an MIMIM structure with five horizontal plates.

FIG. 15A is a Y-axis cross-sectional view of the interconnect structure after the second metal has been applied, and patterning to obtain three horizontal plates.

FIG. 15B is a Y-axis cross-sectional view of the interconnect structure after application of a fourth horizontal plate (insulator) and a fifth horizontal plate (metal) and patterning to obtain a stepped profile that exposes all three metal layers of the capacitor.

FIG. 15G is a Y-axis cross-sectional view of the interconnect structure after application of a capping layer upon the capacitor.

FIG. 15D is a Y-axis cross-sectional view of the final interconnect structure after addition of further interconnect layers and formation of top vias.

FIG. 15E is a Y-axis cross-sectional view of a variation of the capacitor, where no bowed region is present in the capacitor.

FIG. 16 is an alternative method for making an interconnect structure in which a guard ring is formed around a capacitor, in accordance with some embodiments.

FIG. 17A is a Y-axis cross-sectional view of the interconnect structure prior to beginning the method of FIG. 16.

FIG. 17B is a Y-axis cross-sectional view of the interconnect structure after via openings and a guard ring opening are formed.

FIG. 17C is a Y-axis cross-sectional view of the interconnect structure after the via openings and the guard ring opening are filled to form top vias and a guard ring around the capacitor.

FIGS. 17D-17F are various plan views of the interconnect structure, showing different shapes and arrangements of the capacitor and the guard ring.

FIG. 18A is a plan view schematic diagram of a capacitor array with a CMOS image sensor, in accordance with some embodiments.

FIG. 18B is a Y-axis cross-sectional view of an image signal processor (ISP) semiconductor package which is connected to a CMOS image sensor (CIS) package.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The terms “horizontal” and “vertical” as used herein are also spatially relative terms. The term “horizontal” refers to planes parallel to that of the wafer substrate, and the term “vertical” refers to planes that intersect the wafer substrate and form a substantially perpendicular angle with the wafer substrate. “Length” and “width” are measured in the horizontal direction, while “height” or “thickness” or “depth” are measured in the vertical direction.

Numerical values in the specification and claims of this application should be understood to include numerical values which are the same when reduced to the same number of significant figures and numerical values which differ from the stated value by less than the experimental error of conventional measurement technique of the type described in the present application to determine the value. All ranges disclosed herein are inclusive of the recited endpoint.

The term “about” can be used to include any numerical value that can vary without changing the basic function of that value. When used with a range, “about” also discloses the range defined by the absolute values of the two endpoints, e.g. “about 2 to about 4” also discloses the range “from 2 to 4.” The term “about” may refer to plus or minus 10% of the indicated number.

The present disclosure relates to systems and devices which are made up of multiple components and/or different layers. When the terms “on” or “upon” are used with reference to two different components or layers, they indicate merely that one component/layer is on or upon the other component layer. These terms do not require the two components/layers to directly contact each other, and permit other components/layers to be between them. The term “directly” may be used to indicate two components/layers directly contact each other without any other components/layers in between them. In addition, when referring to performing process steps to a component/substrate, this should be construed as performing such steps to whatever layers may be present on the component/substrate as well, depending on the context.

The term “semiconductor package”, as used in the present disclosure, refers to the combination of one or more integrated circuits (also referred to as a die, chip, or microchip) and an interconnect structure that permits the integrated circuit(s) to communicate with one or more other packages. The interconnect structure may be made from one or more interconnect layers. Examples of an interconnect layer may include a redistribution layer (RDL) or an interposer having bond pads or C4 bumps or pillars. A semiconductor package may have an interconnect structure on only one side, or on both sides, as will be seen further herein. It is noted that in the art, the term “package” is used to refer to many different structures and does not have a single fixed definition.

The present disclosure relates to various capacitors that can be present in an interconnect structure, and to methods for making such capacitors. An interconnect structure is built upon a substrate and is formed from a combination of dielectric layers. The dielectric layers include electrically conductive features which are used for communication between various components on the substrate. An interconnect structure may have several dielectric layers, with the conductive features being vertically interconnected by vias.

The capacitors of the present disclosure include several features. In some embodiments, the capacitor may include a bowed region, which can be used for stress relief. In other embodiments, the capacitor may be a metal-insulator-metal (MIM) capacitor or a metal-insulator-metal-insulator-metal (MIMIM) capacitor formed from a combination of a vertical trench and horizontal plates. In still other embodiments, the capacitor may be surrounded by a guard ring that reduces noise and improves reliability of the capacitor.

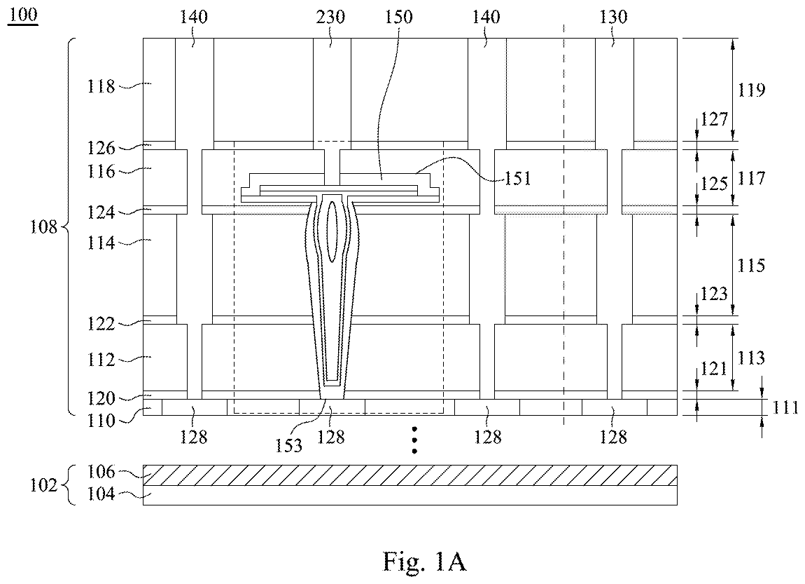

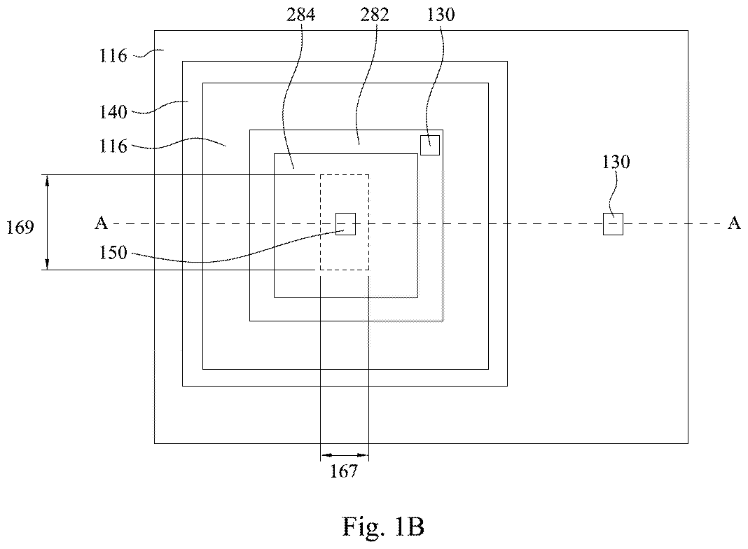

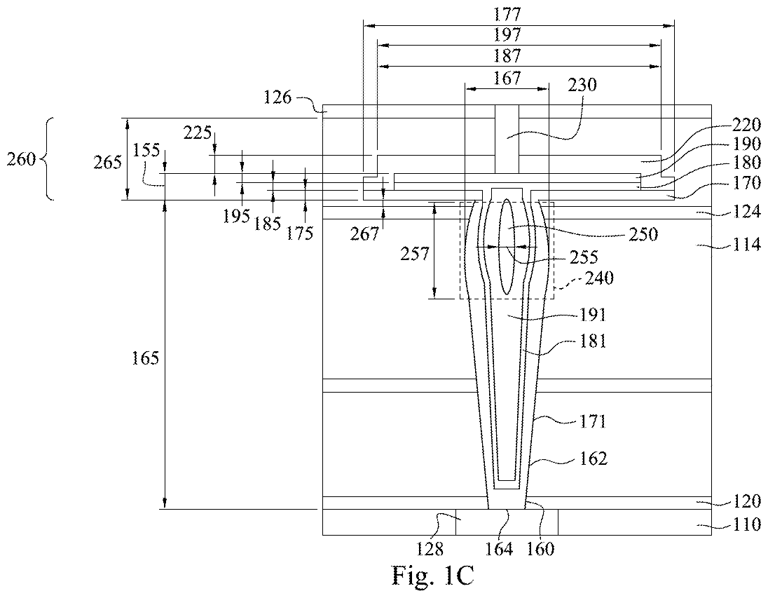

FIG. 1A is a cross-sectional view of one example of a semiconductor package with an interconnect structure of the present disclosure. The interconnect structure includes a capacitor having a bowed region, and also includes a guard ring that surrounds the capacitor. FIG. 1B is a plan view, with FIG. 1A being taken through line A-A. FIG. 1C is a magnified cross-sectional view of the capacitor.

Initially, the semiconductor package 100 includes a semiconductor die 102, upon which the resistor structure will be built. The die includes a substrate 104 and multiple layers upon the substrate which form an integrated circuit, shown here as one layer 106.

The substrate is a wafer made of a semiconducting material in certain embodiments. Such semiconductor materials can include silicon, for example in the form of crystalline Si. In alternative embodiments, the substrate can be made of other elementary semiconductors such as germanium, or may include a compound semiconductor such as silicon carbide (SiC), gallium arsenide (GaAs), gallium carbide, gallium phosphide, indium arsenide (InAs), indium phosphide (InP), silicon germanium, silicon germanium carbide, gallium arsenic phosphide, or gallium indium phosphide. In particular embodiments, the wafer substrate is silicon.

Integrated circuits are built up from different patterns of electrically conductive materials and electrically insulating materials to make useful components. Suitable examples of integrated circuit components may include, for example and without limitation, active components (e.g., transistors), passive components (e.g., capacitors, inductors, resistors, and the like), or combinations thereof. These components may be made from electrically conductive materials such as metals like copper, aluminum, gold, tungsten, iron, ruthenium, iridium, and alloys thereof. Suitable examples of electrically insulating materials (i.e. dielectric materials) may include oxides such as silicon dioxide (SiO₂), aluminum oxide (Al₂O₃), tantalum oxide (Ta₂O₅), zirconium dioxide (ZrO₂), or hafnium dioxide (HfO₂); nitrides such as silicon carbon nitride (SiCN), silicon nitride (SiN), hafnium oxynitride (HfOₓN_{y}), zirconium oxynitride (ZrOₓN_{y}), or silicon oxynitride (SiOₓN_{y}), where 0<x, y, ≤1; silicates like hafnium silicates (HfSiₓO_{y}) or zirconium silicates (ZrSiₓO_{y}), where 0<x, y, ≤1; polysilicon, phosphosilicate glass (PSG), fluorosilicate glass (FSG), undoped silicate glass (USG), high-stress undoped silicate glass (HSUSG), borosilicate glass (BSG), a high-k dielectric material, or a low-k dielectric material.

Continuing, the interconnect structure 108 includes multiple interconnect or dielectric layers and etch stop layers. The interconnect layers may independently be considered intermetal dielectric (IMD) layers or interlayer dielectric (ILD) layers. These dielectric layers may be at any level within the interconnect structure upon the semiconductor die 102. Illustrated here are five interconnect or dielectric layers 110, 112, 114, 116, 118, separated by four etch stop layers 120, 122, 124, 126. However, any number of interconnect layers and etch stop layers may be present in the interconnect structure. Metal contacts 128 are illustrated as being present within the first dielectric layer 110, which is proximate the semiconductor die.

The dielectric layers may have the same or different composition, and may be made from the dielectric materials previously listed above. In particular embodiments, the dielectric layers are formed from silicon oxide (SiOₓ), Adjacent etch stop layers are usually made from different materials, which may also be dielectric materials. In particular embodiments, the etch stop layers are made from SiN, SiC, TiN, and AlOₓ(0<x≤1).

Referring to FIG. 1A, in some embodiments, the thickness 111 of the first dielectric layer 110 is from about 700 angstroms to about 1000 angstroms (or about 70 nanometers to about 100 nm). In some embodiments, the thickness 121 of the first etch stop layer 120 is from about 150 angstroms to about 300 angstroms. In some embodiments, the thickness 113 of the second dielectric layer 112 is from about 500 angstroms to about 7500 angstroms. In some embodiments, the thickness 123 of the second etch stop layer 120 is from about 400 angstroms to about 600 angstroms. In some embodiments, the thickness 115 of the third dielectric layer 114 is from about 1500 angstroms to about 20,000 angstroms. In some embodiments, the thickness 125 of the third etch stop layer 124 is from about 150 angstroms to about 350 angstroms. In some embodiments, the thickness 117 of the fourth dielectric layer 116 is from about 5500 angstroms to about 7500 angstroms. In some embodiments, the thickness 127 of the fourth etch stop layer 126 is from about 400 angstroms to about 600 angstroms. In some embodiments, the thickness 119 of the fifth dielectric layer 118 is from about 1500 angstroms to about 20,000 angstroms. However, other values and ranges for each of these layers are also within the scope of this disclosure.

Next, a through-via 130 is illustrated on the right-hand side of FIG. 1A. A guard ring 140 is also illustrated surrounding the capacitor 150. The top of the capacitor defines a top level 151, and the bottom of the capacitor defines a bottom level 153. The guard ring 140 forms a solid wall around the capacitor between the top level 151 and the bottom level 153.

FIG. 1B is a slice through dielectric layer 116. As more clearly seen here, the guard ring 140 surrounds the capacitor 150. The capacitor bottom metal or CBM 282 and the capacitor top metal or CTM 284 are shown, along with two top vias 230. Two through-vias 130 are also illustrated.

The trench 160 is represented by a dotted box. In some embodiments, the trench 160 has a length 169 of about 5000 angstroms to about 10,000 angstroms. In some embodiments, the trench 160 has a width 167 of about 1000 angstroms to about 3000 angstroms. However, other values and ranges for each of these measurements are also within the scope of this disclosure.

Referring now to FIG. 1C, as illustrated here, the capacitor 150 is formed from electrically conductive metals and electrically insulating dielectric materials (i.e. insulators) which are arranged within a vertical trench 160 and as a set of horizontal plates 170, 180, 190.

A first metal layer 171 conforms to the sidewalls 162 and the bottom surface 164 of the trench. The first metal layer also forms a first horizontal plate 170. The first metal layer and the first horizontal plate are, in particular embodiments, both formed from a first metal.

A first insulator layer 181 is present upon the first metal layer 171. The first insulator layer also conforms to the sidewalls and the bottom surface of the trench. The first insulator layer also forms a second horizontal plate 180 upon the first horizontal plate. The first insulator layer and the second horizontal plate are, in particular embodiments, both formed from a first insulator.

A second metal layer 191 is present upon the first insulator layer 181. The second metal also conforms to the sidewalls and the bottom surface of the trench. The second metal also surrounds a second insulator. The second metal layer is also deposited over the second insulator, and can also be described as encapsulating the second insulator. As illustrated here, the second insulator may also be considered to be a void 250, which is filled with air or another gas. Also as illustrated here, the second horizontal plate 180 covers the second metal layer 191 and isolates the second metal layer. The second metal layer is formed from a second metal.

A third horizontal plate 190 is present upon the second horizontal plate 180. The third horizontal plate is formed from a third metal. It is noted that the horizontal plates have a stepped profile in this cross-section, with the first horizontal plate 170 having a width 177 that is greater than the width 187 of the second horizontal plate. The width 177 of the first horizontal plate is also greater than the width 197 of the third horizontal plate. The width 187 of the second horizontal plate is greater than or equal to the width 197 of the third horizontal plate, so as to electrically isolate the first horizontal plate 170 from the third horizontal plate 190. This permits top vias to be formed to each of the metal horizontal plates. However, this relationship is not always required, for example when the first horizontal plate can be accessed by a metal contact 128.

In particular embodiments, the first metal, the second metal, and the third metal may be an elemental metal or a metal alloy. Examples of suitable materials may include, for example, TiN, TaN, Ti, or Ta. In particular embodiments, the first insulator is a high-k dielectric material, such as HfOₓ, AlOₓ, or ZrOₓ (0<x≤1).

Finally, a capping layer 220 is present over the first horizontal plate 170, the second horizontal plate 180, and the third horizontal plate 190. The capping layer conforms to the shape of the horizontal plates, and is used as an etch stop layer. The capping layer may be made from any suitable dielectric material. In particular embodiments, the capping layer is formed from SiN or SiC.

Referring to FIG. 1C, in some embodiments, the thickness 175 of the first horizontal plate 170 is from about 1000 angstroms to about 3000 angstroms. In some embodiments, the thickness 185 of the second horizontal plate 180 is from about 20 angstroms to about 100 angstroms. In some embodiments, the thickness 195 of the third horizontal plate 190 is from about 1000 angstroms to about 3000 angstroms. In some embodiments, the thickness 225 of the capping layer 220 is from about 700 angstroms to about 1200 angstroms. In some embodiments, the trench 160 has a depth 165 of about 200 angstroms to about 30,000 angstroms. The trench depth is measured from the bottom surface of the first horizontal plate to the bottom surface 164 of the trench. However, other values and ranges for each of these measurements are also within the scope of this disclosure.

In FIG. 1A and FIG. 1C, a top via 230 extends through the interconnect structure and contacts the third horizontal plate 190 (CTM) of the capacitor. As seen in the plan view of FIG. 1B, another top via 230 also extends through the interconnect structure to contact the first horizontal plate 170 (CBM) of the capacitor.

Referring now to FIG. 1C, the trench 160 of the capacitor 150 includes a bowed region 240 (indicated by a dashed box). Typically, the length and width of a trench decreases from the top of the trench to the bottom surface of the trench in a relatively linear fashion, due to the etching process. In the bowed region, however, the length and/or width of the trench increases and then decreases in a non-linear fashion. In particular embodiments, the bowed region is located between 2% and 98% of the depth of the trench (where 0% is at the top of the trench and 100% is at the bottom of the trench). As illustrated here, the bowed region is near the top of the trench.

FIG. 1C also illustrates a void 250, which contains air or another gas, and thus acts as a second insulator. The top of the trench has a width 167, and the void has a width 255. In particular embodiments, the width 255 of the void (measured at its widest point) is from about 1% to about 20% of the width 167 at the top of the trench. The void also has a depth 257. In particular embodiments, the depth 257 of the void is from about 10% to about 50% of the depth 165 of the trench.

The aspect ratio of the trench may be measured as the ratio of the trench depth 165 to the trench width 167, In particular embodiments, the aspect ratio of the trench is from about 3 to about 15, and in more specific embodiments from about 11 to about 15. Other values and ranges for each of these measurements are also within the scope of this disclosure.

Referring still to FIG. 1C, the three horizontal plates 170, 180, 190 of the capacitor are generally located in a dielectric layer 260 between two etch stop layers 124, 126. Together the three horizontal plates have a thickness 155. In particular embodiments, the combined thickness 155 of the three horizontal plates is at most about 50% of the thickness 265 of the dielectric layer. Other values and ranges are also within the scope of this disclosure.

It is noted that as best seen in FIG. 1C, the first horizontal plate 170 is embedded within the dielectric layer 260, rather than upon the etch stop layer 124. The thickness of the dielectric layer between the etch stop layer 124 and the first horizontal plate 170 is indicated with reference numeral 267. In particular embodiments, this thickness 267 is from about 500 angstroms to about 3000 angstroms. Other values and ranges are also within the scope of this disclosure. It should also be noted that the trench 160 is illustrated as extending through the first etch stop layer 120. Thus, the capacitor 150 can contact the metal contact 128 in the first dielectric layer 110 if desired. However, this is not required.

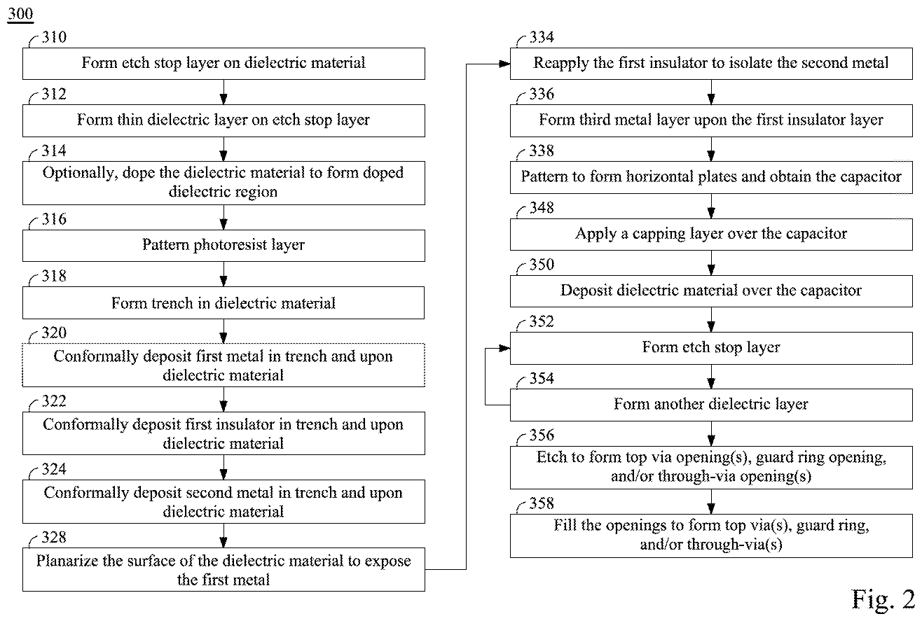

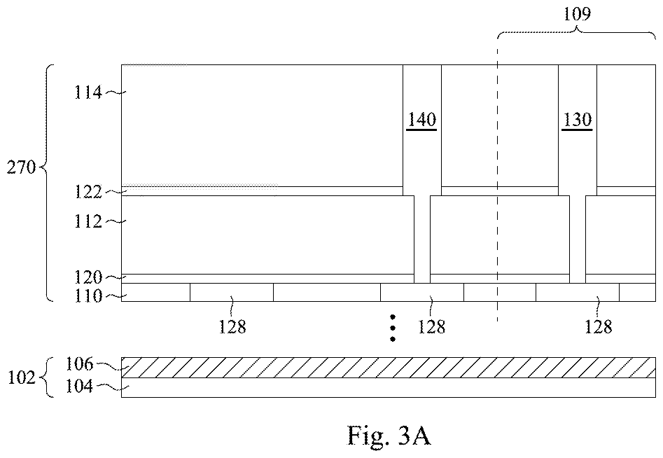

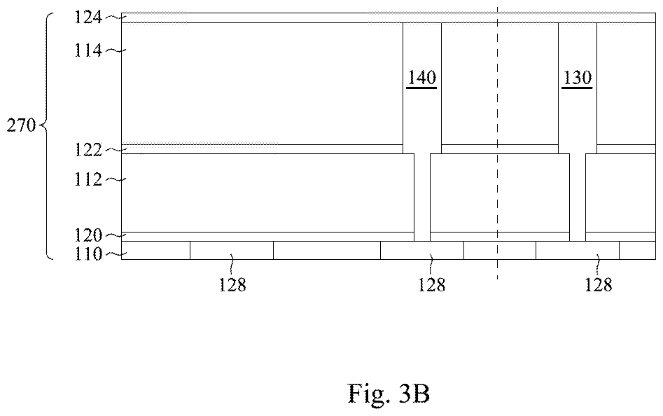

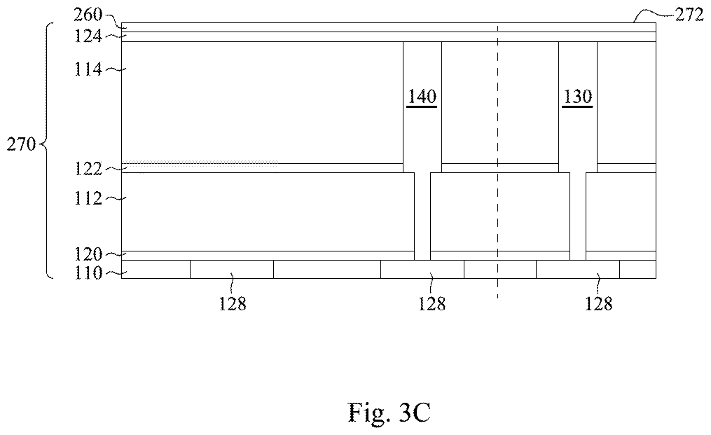

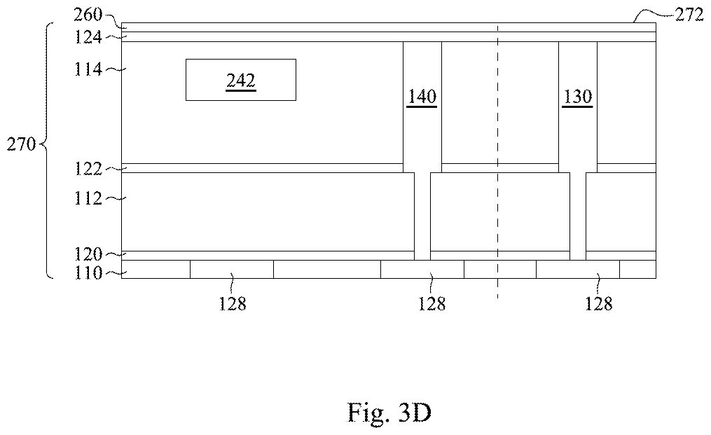

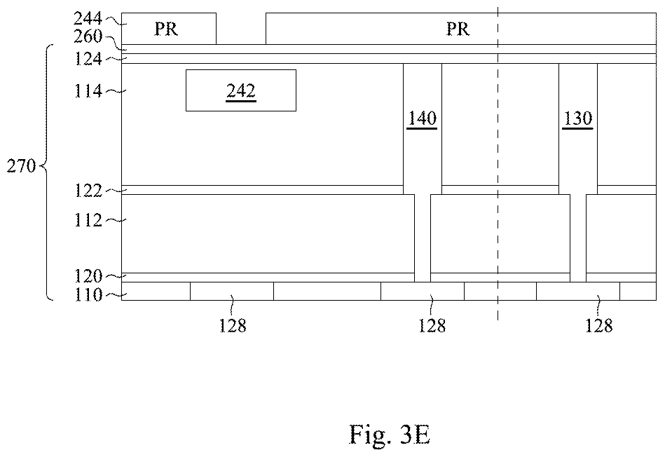

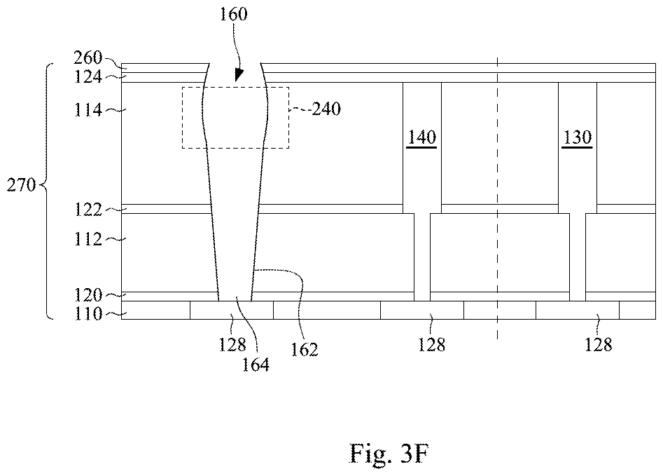

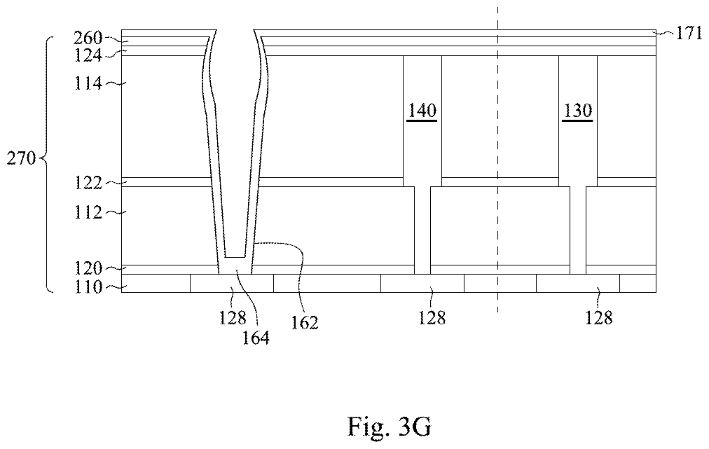

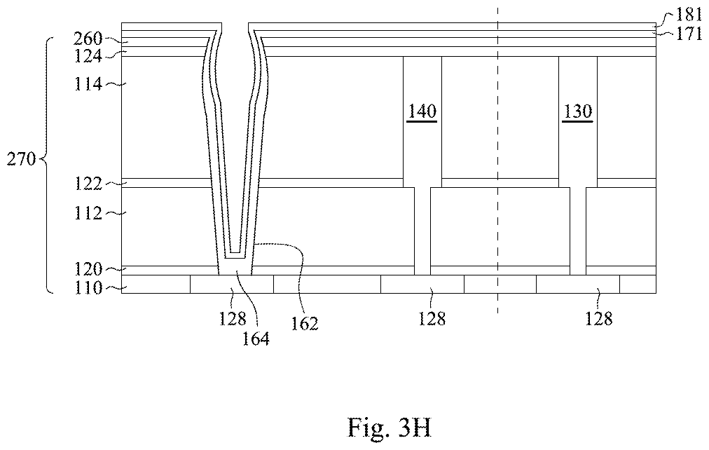

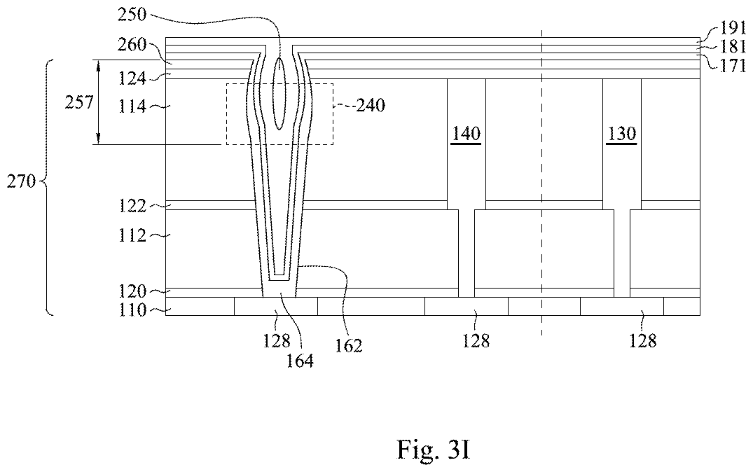

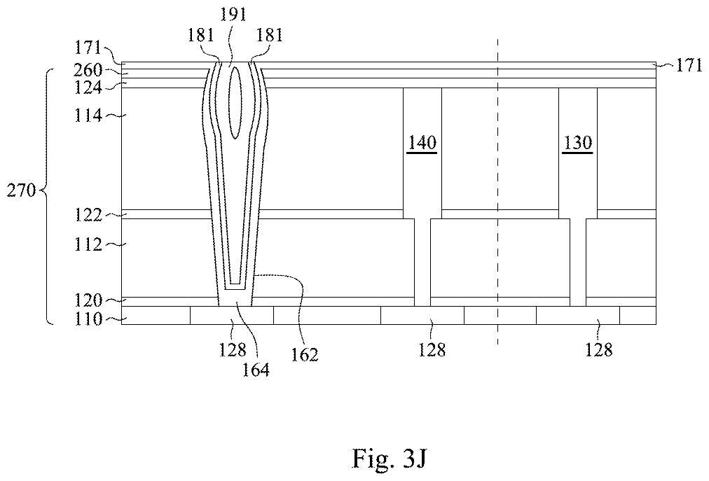

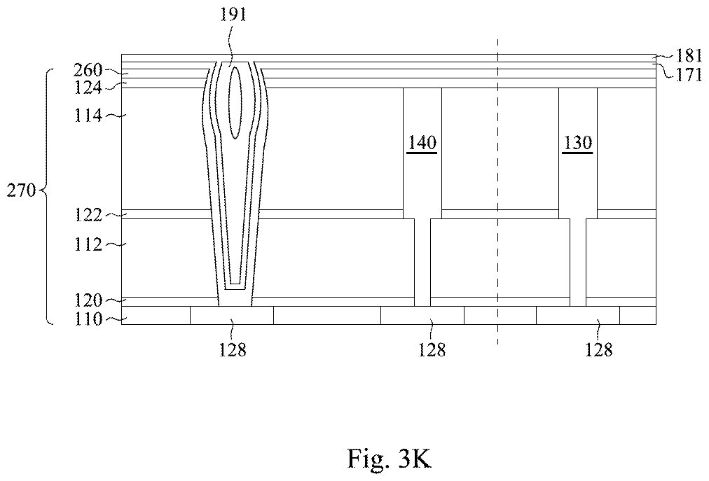

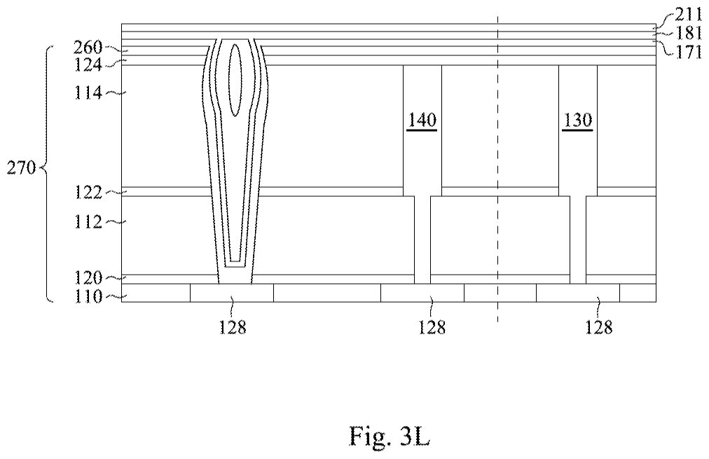

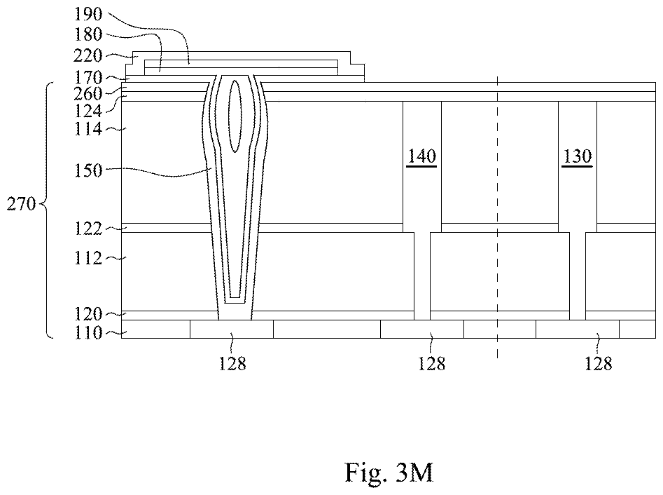

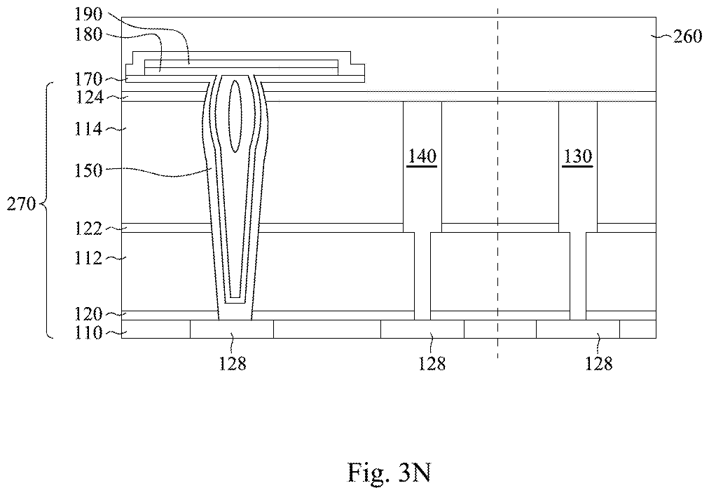

FIG. 2 is a flow chart illustrating a first method 300 for making an interconnect structure, in accordance with some embodiments. Some steps of the method are also illustrated in FIGS. 3A-3P, which are Y-axis cross-sectional views. These figures provide different views for better understanding. While the method steps are discussed below in terms of forming a single capacitor, guard ring, and through-via, such discussion should also be broadly construed as applying to the formation of multiple structures concurrently.

It is noted that certain conventional steps are not expressly described in the discussion below. For example, a pattern/structure may be formed in a given layer by applying a photoresist layer, patterning the photoresist layer, developing the photoresist layer, and then etching.

Generally, a photoresist layer may be applied, for example, by spin coating, or by spraying, roller coating, dip coating, or extrusion coating. Typically, in spin coating, the substrate is placed on a rotating platen, which may include a vacuum chuck that holds the substrate in plate. The photoresist composition is then applied to the center of the substrate. The speed of the rotating platen is then increased to spread the photoresist evenly from the center of the substrate to the perimeter of the substrate. The rotating speed of the platen is then fixed, which can control the thickness of the final photoresist layer.

Next, the photoresist composition is baked or cured to remove the solvent and harden the photoresist layer. In some particular embodiments, the baking occurs at a temperature of about 90° C. to about 110° C. The baking can be performed using a hot plate or oven, or similar equipment. As a result, the photoresist layer is formed on the substrate.

The photoresist layer is then patterned via exposure to radiation. The radiation may be any light wavelength which carries a desired mask pattern. In particular embodiments, EUV light having a wavelength of about 13.5 nm is used for patterning, as this permits smaller feature sizes to be obtained. This results in some portions of the photoresist layer being exposed to radiation, and some portions of the photoresist not being exposed to radiation. This exposure causes some portions of the photoresist to become soluble in the developer and other portions of the photoresist to remain insoluble in the developer.

An additional photoresist bake step (post exposure bake, or PEB) may occur after the exposure to radiation. For example, this may help in releasing acid leaving groups (ALGs) or other molecules that are significant in chemical amplification photoresist.

The photoresist layer is then developed using a developer. The developer may be an aqueous solution or an organic solution. The soluble portions of the photoresist layer are dissolved and washed away during the development step, leaving behind a photoresist pattern. One example of a common developer is aqueous tetramethylammonium hydroxide (TMAH). Generally, any suitable developer may be used. Sometimes, a post develop bake or “hard bake” may be performed to stabilize the photoresist pattern after development, for optimum performance in subsequent steps.

Continuing, portions of the layer below the patterned photoresist layer are now exposed. Etching transfers the photoresist pattern to the layer below the patterned photoresist layer. After use, the patterned photoresist layer can be removed, for example, using various solvents such as N-methyl-pyrrolidone (NMP) or alkaline media or other strippers at elevated temperatures, or by dry etching using oxygen plasma.

Generally, any etching step used herein may be performed using wet etching, dry etching, or plasma etching processes such as reactive ion etching (RIE) or inductively coupled plasma (ICP), or combinations thereof, as appropriate. The etching may be anisotropic. Depending on the material, etchants may include carbon tetrafluoride (CF₄), hexafluoroethane (C₂F₆), octafluoropropane (C₃F₈), fluoroform (CHF₃), difluoromethane (CH₂F₂), fluoromethane (CH₃F), carbon fluorides, nitrogen (Nz), hydrogen (H₂), oxygen (Oz), argon (Ar), xenon (Xe), xenon difluoride (XeF₂), helium (He), carbon monoxide (CO), carbon dioxide (CO₂), fluorine (F₂), chlorine (Cl₂), hydrogen bromide (HBr), hydrofluoric acid (HF), nitrogen trifluoride (NF₃), sulfur hexafluoride (SF₆), boron trichloride (BCl₃), ammonia (NH₃), bromine (Bra), nitrogen trifluoride (NF₃), or the like, or combinations thereof in various ratios. For example, silicon dioxide can be wet etched using hydrofluoric acid and ammonium fluoride. Alternatively, silicon dioxide can be dry etched using various mixtures of CHF₃, O₂, CF₄, and/or Hz.

Planarization of a surface may be performed, for example, using a chemical mechanical polishing (CMP) process. Generally, CMP is performed using a rotating platen to which a polishing pad is attached. The substrate is attached to a rotating carrier. A slurry or solution containing various chemicals and abrasives is dispensed onto the polishing pad or the wafer substrate. During polishing, both the polishing pad and the carrier rotate, and this induces mechanical and chemical effects on the surface of the wafer substrate and/or the top layer thereon, removing undesired materials and creating a highly level surface. A post-CMP cleaning step is then carried out using rotating scrubber brushes along with a washing fluid to clean one or both sides of the wafer substrate.

FIG. 3A is a cross-sectional view of the interconnect structure prior to beginning the method. As illustrated here, a logic region 109 is present on the right-hand side, as indicated with the dashed line. A partial through-via 130 is present in the logic region. Continuing, metal contacts 128 have been formed upon the substrate 104 or upon the semiconductor die 102. The first dielectric layer 110 is formed upon the substrate, and also covers the metal contacts. The first etch stop layer 120 has been formed upon the first dielectric layer 110. The second dielectric layer 112, the second etch stop layer 122, and the third dielectric layer 114 are also illustrated. Together, they are referred to further as a dielectric material 270. Only one side of the guard ring 140 is illustrated here. The guard ring 140 and the through-via 130 have been partially formed. The semiconductor die 102 is omitted in further figures for convenience.

Starting then at step 310 of FIG. 2 and as illustrated in FIG. 3B, an etch stop layer 124 is formed upon a dielectric material 270.

Then, in step 312 of FIG. 2 and as illustrated in FIG. 3C, a dielectric layer 260 is formed upon the etch stop layer 124. The dielectric layer may be planarized. Referring back to FIG. 1C, this dielectric layer 260 corresponds to the portion between the etch stop layer 123 and the first horizontal plate 170 having thickness 265. The dielectric layer 260 forms a top surface 272 of the dielectric material/structure. This will permit better etch profile control during etching to form the trench 160.

Next, in optional step 314 of FIG. 2 and as illustrated in FIG. 3D, the dielectric material is doped to form a doped dielectric region 242. This may be done, for example, using ion implantation or other suitable process. Briefly, an ion implanter is used to implant atoms, modifying the etch selectivity of the dielectric material in the implanted location. An ion implanter generally includes an ion source, a beam line, and a process chamber. The ion source produces the desired ions (here, for example, boron (B) or arsenic (As)). The beam line organizes the ions into a beam having high purity in terms of ion mass, energy, and species. A mask, such as a patterned photoresist layer or a hard mask layer, is used to expose desired regions of the dielectric material. The ion beam is then used to irradiate the semiconducting wafer substrate in a process chamber. The ion beam strikes the exposed regions and the ions can be implanted into the dielectric material as dopants at desired depths. This step results in the capacitor having a bowed region.

Then, in step 316 of FIG. 2 and as illustrated in FIG. 3E, a photoresist layer 244 is applied and patterned to expose the desired location(s) of the trench(es) for the capacitor. Then, in step 318 of FIG. 2 and as illustrated in FIG. 3F, a trench 160 is formed in the dielectric material. This is typically done by etching. In this regard, the etchant has a higher etch selectivity for the material in the doped dielectric region compared to the dielectric material, and thus etches sideways into the doped dielectric region more quickly than downwards into the dielectric material. As illustrated here, after the photoresist layer is removed, the resulting trench has a bowed region 240 in a location corresponding to the doped dielectric region of FIG. 3D. The trench sidewalls 162 and bottom surface 164 are also most visible here.

Next, in step 320 of FIG. 2 and as illustrated in FIG. 3G, a first metal is deposited on the sidewalls 162 and the bottom surface 164 of the trench, as well as upon the surface of the dielectric material, in a conformal manner. The deposited layer is referred to herein as a first metal layer 171. This conformal deposition may be performed by chemical vapor deposition (CVD), physical vapor deposition (PVD), atomic layer deposition (ALD), or other suitable deposition technique.

Next, in step 322 of FIG. 2 and as illustrated in FIG. 3H, a first insulator is deposited upon the first metal layer 171 on the sidewalls and the bottom surface of the trench, as well as upon the surface of the dielectric material, in a conformal manner. The deposited layer is referred to herein as a first insulator layer 181. This may be done by CVD, PVD, ALD, or other deposition process.

Then, in step 324 of FIG. 2 and as illustrated in FIG. 3I, a second metal is deposited upon the first insulator layer 181 on the sidewalls and the bottom surface of the trench, as well as upon the surface of the dielectric material, in a conformal manner. The deposited layer is referred to herein as a second metal layer 191. This may be done by CVD, PVD, ALD, or other deposition process.

As illustrated here, the second metal fills the gap at the top of the trench, creating a void 250 within the trench. The void can be considered a second insulator. Thus, the second metal layer also covers the second insulator. Generally, a large portion of the void is located within the bowed region. For example, at least 50% of the void depth 257 may be present within the bowed region 240.

Continuing, in step 328 of FIG. 2 and as illustrated in FIG. 3J, the portions of the second metal layer and the first insulator layer upon the surface are removed from the surface of the dielectric material. This may be done, for example, by planarization processes such as CMP. The horizontal portion of the first metal layer 171 is thus exposed, and is separated from the second metal layer 191 in the trench by the first insulator layer 181.

Then, in step 334 of FIG. 2 and as illustrated in FIG. 3K, a primary insulator is applied upon the surface of the dielectric material. In some particular embodiments, the primary insulator is the same as the first insulator, and so in this illustration the layer is still referred to as the first insulator layer 181. As a result, the second metal 191 is isolated in the trench.

Next, in step 336 of FIG. 2 and as illustrated in FIG. 3L, a third metal layer 211 is formed upon the first insulator layer 181. Then, in step 338 of FIG. 2, patterning is performed to form a first horizontal plate 170 from the first metal layer, a second horizontal plate 180 from the first insulator layer, and a third horizontal plate 190 from the third metal layer. The capacitor 150 is thus formed. Then, in step 348 of FIG. 2, a capping layer 220 is applied over the three horizontal plates. The resulting structure is Illustrated in FIG. 3M. As seen here, the first horizontal plate 170 and the third horizontal plate 190 are both exposed from the top.

Next, in step 350 of FIG. 2 and as illustrated in FIG. 3N, additional dielectric material is deposited to cover the capacitor. As a result, the horizontal plates 170, 180, 190 of the capacitor are embedded within a dielectric layer 260.

Then, in step 352 of FIG. 2, an etch stop layer 126 is formed upon the dielectric layer 260. In step 354 of FIG. 2, a dielectric layer is formed upon the etch stop layer 126. These two steps 352, 354 can be repeated as desired. The resulting structure is shown in FIG. 3O, after addition of etch stop layer 126 and interconnect layer 118.

In step 356 of FIG. 2, and as illustrated in FIG. 3P, etching is performed to form top via openings 232 to the capacitor. A guard ring opening 142 may also be formed, as well as a through-via opening 132. Then, in step 358 of FIG. 2, the top via openings 232, guard ring opening 142, and through-via opening 132 are filled with appropriate material to obtain top vias 230, the guard ring 140, and the through-via 130. As illustrated in FIGS. 3A-3P, the guard ring 140 and the through-via 130 are formed through multiple opening and filling steps. The resulting structure is seen in FIG. 1A.

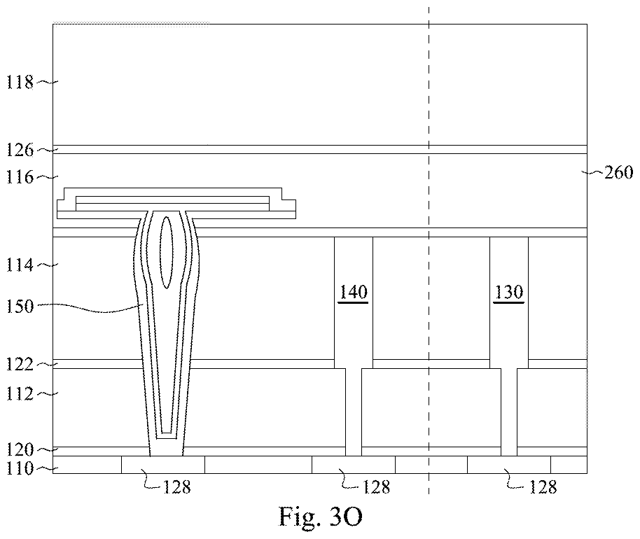

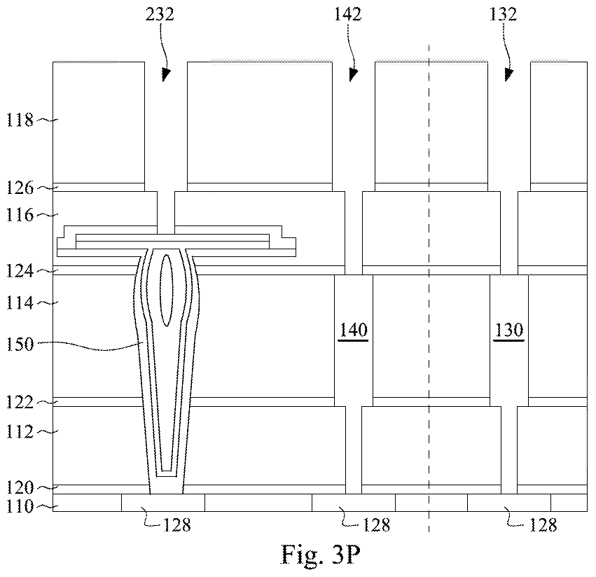

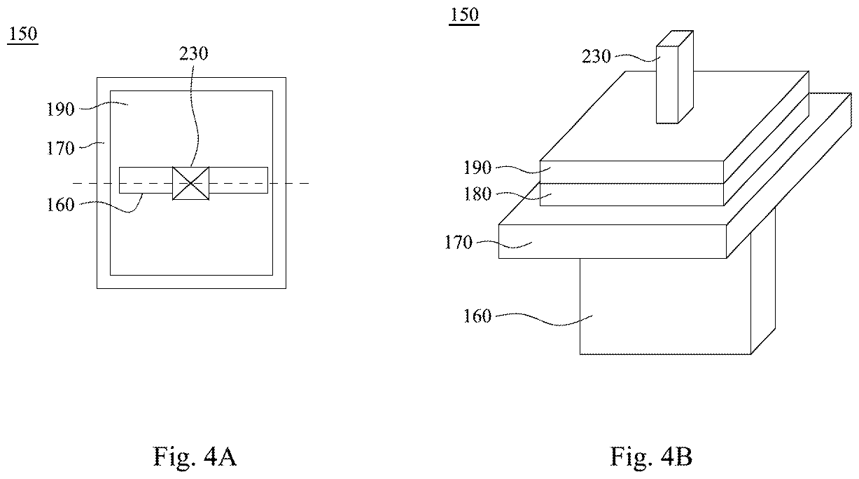

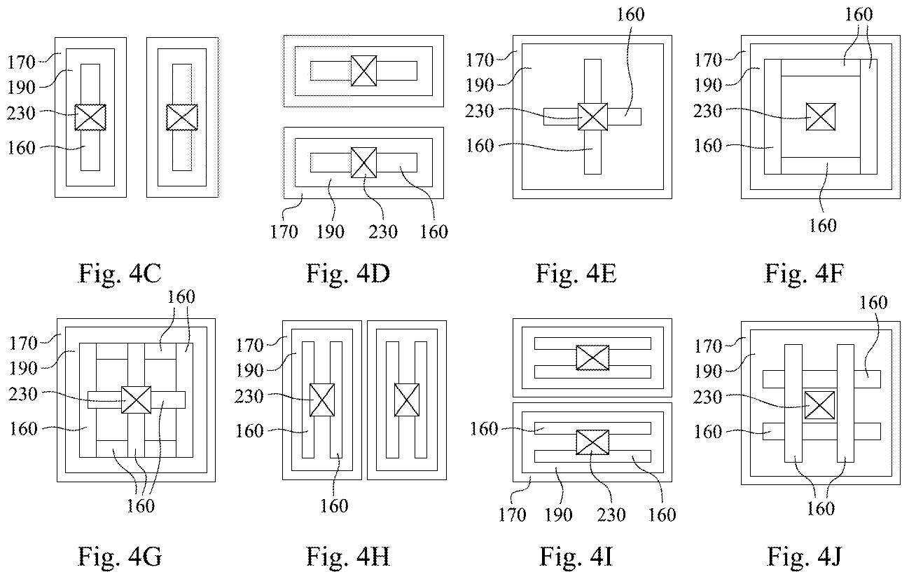

FIG. 4A is a plan view of one arrangement of the trench and horizontal plates of the capacitor 150. Dotted line A-A indicates the plan through which FIG. 1A is taken. In FIG. 4A, the capping layer is not shown. The capacitor bottom metal or CBM (here the first horizontal plate 170) and the capacitor top metal or CTM (here the third horizontal plate 190) are shown. The trench 160 is shown as a rectangle and extends downward into the page, and only one top via 230 is illustrated in the center of the third horizontal plate. FIG. 4B is a perspective view of the capacitor of FIG. 4A. Here, the second horizontal plate 180 is visible.

FIGS. 4C-4J are various plan views of the capacitor in accordance with some embodiments, showing different shapes and arrangements of the trench 160, the top via 230, the CBM 282, and the CTM 284 of capacitor(s) which can be used to optimize the density and capacitance for various applications. About the same surface area is used in each figure, and these are merely illustrative non-limiting examples.

In FIG. 4C, two capacitors are arranged lengthwise. In FIG. 4D, two capacitors are arranged widthwise. In FIG. 4E, the capacitor includes two trenches which intersect at their center to form a cross. In FIG. 4F, the capacitor includes four trenches. Two trenches are arranged in the X-axis, and two trenches are arranged in the Y-axis. The four trenches intersect at their ends to form a square-shaped annular trench. In FIG. 4G, two capacitors are arranged lengthwise. Each capacitor has two parallel trenches. In FIG. 4H, two capacitors are arranged widthwise. Each capacitor has two parallel trenches. In FIG. 4I, the capacitor has four trenches which are arranged to form the shape of the number sign, hash, or pound sign. In FIG. 4J, the capacitor has six trenches which are arranged to form the shape of a large square which is divided into four smaller squares. The top via 230 is shown in the center of the CTM in these examples, but can be located anywhere in the surface area of the CTM.

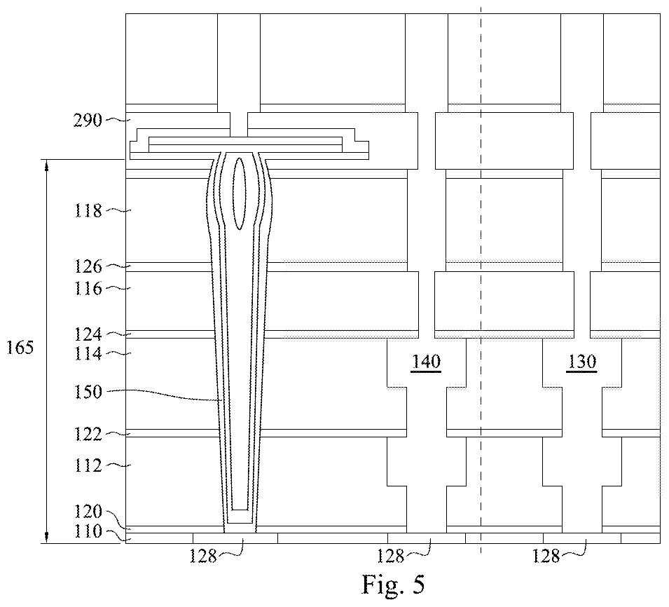

The various dimensions of the capacitor may be varied as desired. FIG. 5 is a Y-axis cross-sectional view illustrating such one variation of the capacitor, Here, the trench depth 165 is much deeper than the capacitor of FIG. 1A. As a result, the aspect ratio of the capacitor (trench depth to plate width) is also higher. In FIG. 1A, the capacitor is present in three different dielectric layers 112, 114, 116. In contrast, in FIG. 5, the capacitor is present in five different dielectric layers 112, 114, 116, 118, 290. Generally, the capacitor may be present in any desired number of dielectric layers, including as few as one dielectric layer.

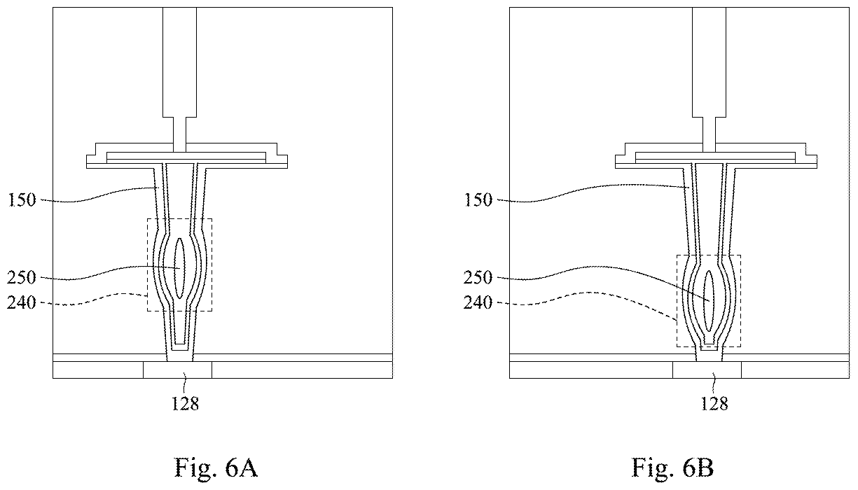

FIG. 6A and FIG. 6B are cross-sectional views illustrating additional variations of the capacitor 150. In FIG. 1A, the bowed region is near the top of the trench. In FIG. 6B, the bowed region 240 is in the middle of the trench. In FIG. 6C, the bowed region 240 is near the bottom of the trench. The void 250 changes location as well. The location of the bowed region is based on the location of the doped dielectric region, and so the location of doping step 314 in the method of FIG. 2 may change depending on where the bowed region is desired. For example, if the bowed region is desired to be near the bottom of the trench as in FIG. 6C, it may be desirable to dope the second dielectric layer 112 before forming the other dielectric layers 114, 116, 118.

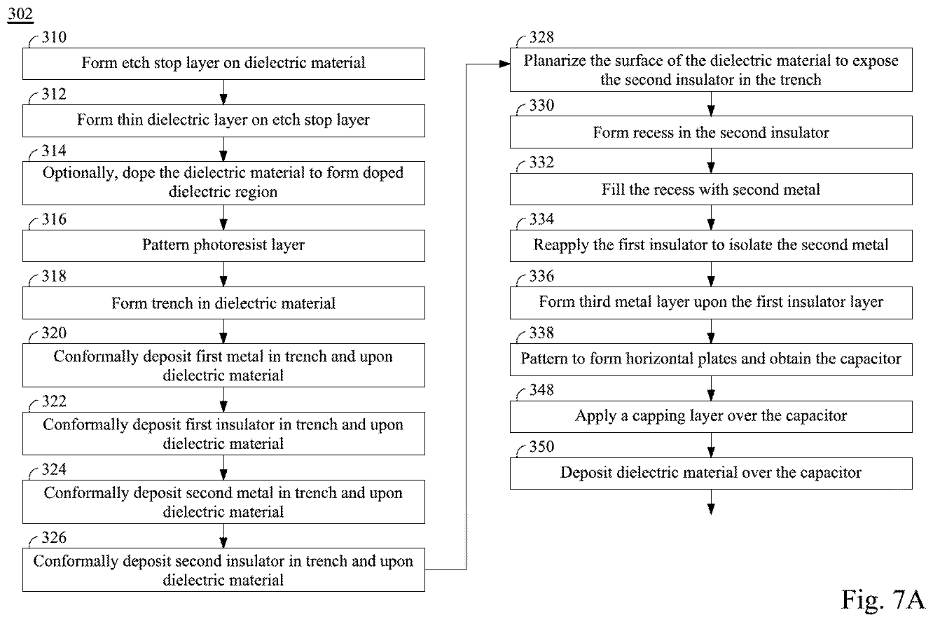

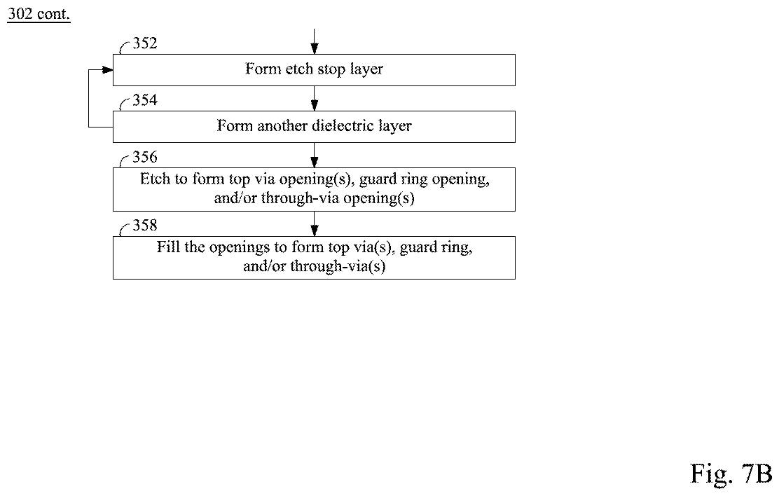

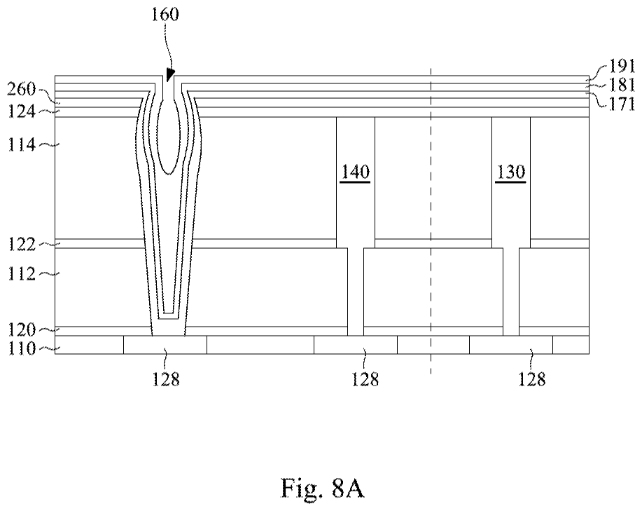

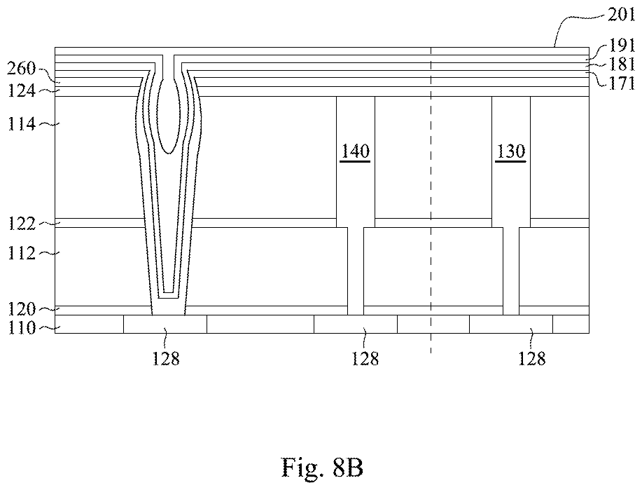

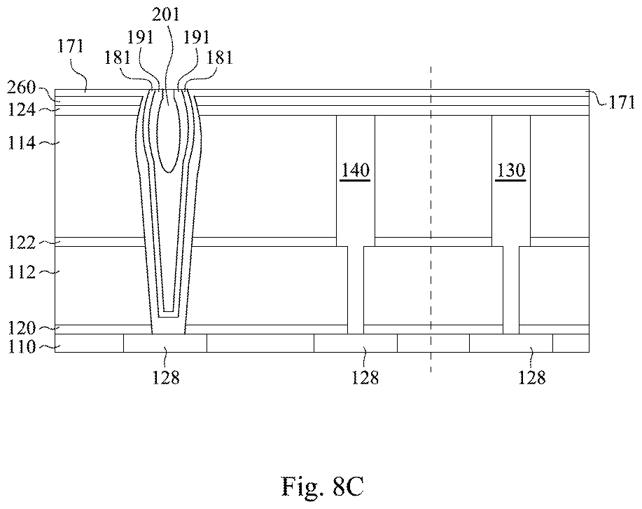

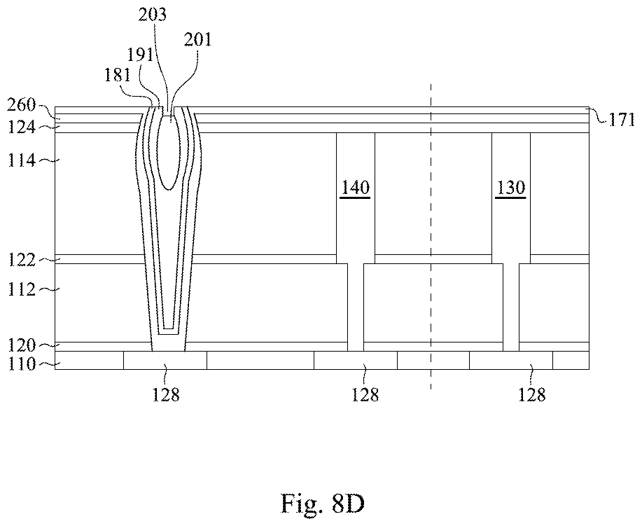

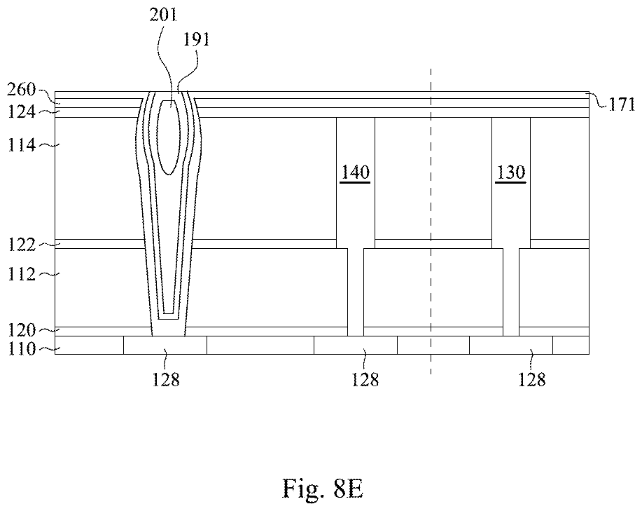

In the method of FIG. 2 and as illustrated in FIGS. 3A-3P, the second insulator is an air void. However, it is also contemplated that a second insulator material could be deposited into the trench. FIG. 7A and FIG. 7B together illustrate a second method 302 for making such an interconnect structure, in accordance with some embodiments. Here, a second insulator is included in the trench of the insulator. Some steps of the method are also illustrated in FIGS. 8A-8E.

Steps 310-324 of FIG. 7A are generally the same as FIG. 2. However, FIG. 7A differs after step 324. As discussed above with respect to step 324 and FIG. 3I, in the first method of FIG. 2, the second metal fills the gap at the top of the trench, creating a void 250 within the trench. However, as Illustrated in FIG. 8A, the second metal does not fill the gap at the top of the trench. Thus, additional material can still be deposited into the trench 160.

Continuing, then, in step 326 of FIG. 7A and as illustrated in FIG. 8B, a second insulator is deposited upon the second metal layer 191 on the sidewalls and the bottom surface of the trench in a conformal manner, and may also be deposited upon the surface of the dielectric material. The deposited layer is referred to herein as a second insulator layer 201. This may be done by CVD, PVD, ALD, or other deposition process.

In particular embodiments, the second insulator is silicon nitride (SiN), which can provide tensile or compressive stress to balance out any stresses in the interconnect structure. In this regard, the silicon nitride can be deposited using ALD (for high aspect ratio trench filling) or CVD. Common growth temperatures for silicon nitride range from 200° C. to 800° C. Silicon precursors for deposition may include silanes and halogenated silane. Examples may include but are not limited to tetraethyl orthosilicate (TEOS), trimethylsilane, tetramethylsilane, hexachlorodisilane (HCDS), iodosilane, and other chlorosilanes. Nitrogen precursors for deposition may include but are not limited to ammonia (NH₃), N₂, and N₂O. To facilitate dissociation of the precursors, a plasma source, such as ICP (Inductively Coupled Plasma) or CCP (Capacitively Coupled Plasma), may be used. To better control the dissociation rates of the precursor and the viscosity of the precursors flowing to the wafer substrate, other gases such as argon, hydrogen, or nitrogen may be included as well to facilitate dissociation or reduce the viscosity.

The stress applied by SiN can be tuned/controlled/changed through (1) changing the deposition or growth temperature to control the degree of thermal expansion of the resulting SiN; (2) using different precursors to change the crystalline qualities of the resulting SiN; and/or (3) changing how the precursors are dissociated to control the material that starts the growth of the SiN. For example, generally, higher growth temperatures will lead to the formation of a layer with more tensile stress. For example, by raising the growth temperature into the range of 400° C. to 600° C., the stress of the SiN can increase 3.2 MPa/° C. for an SiN layer with a thickness of about 200 nm to about 300 nm. SiN can also be made to exert more tensile stress by reducing the amount of impurities in the SiN. This can be done, for example, by increasing the dissociation rates of the precursor by using plasma source or including gases such as argon or hydrogen.

Next, in step 328 of FIG. 7A and as illustrated in FIG. 8C, the surface of the dielectric material is planarized to remove the portions of the second insulator layer, the second metal layer, and the first insulator layer upon the surface. This may be done, for example, by CMP. The horizontal portion of the first metal layer 171 is thus exposed. The second insulator layer 201 which is surrounded by the second metal layer 191, is also exposed.

Next, in step 330 of FIG. 7A and as illustrated in FIG. 8D, a recess 203 is formed in the second insulator layer 201. This may be done, for example, by etching. Then, in step 332 of FIG. 7A and as illustrated in FIG. 8E, the recess is filled with the second metal 191. Additional planarization may be performed as needed to remove excess second metal. This resulting structure is thus functionally identical to FIG. 3J. The following steps 334-358 of FIG. 7A and FIG. 7B are then identical to FIG. 2, and as Illustrated in FIGS. 3K-3P.

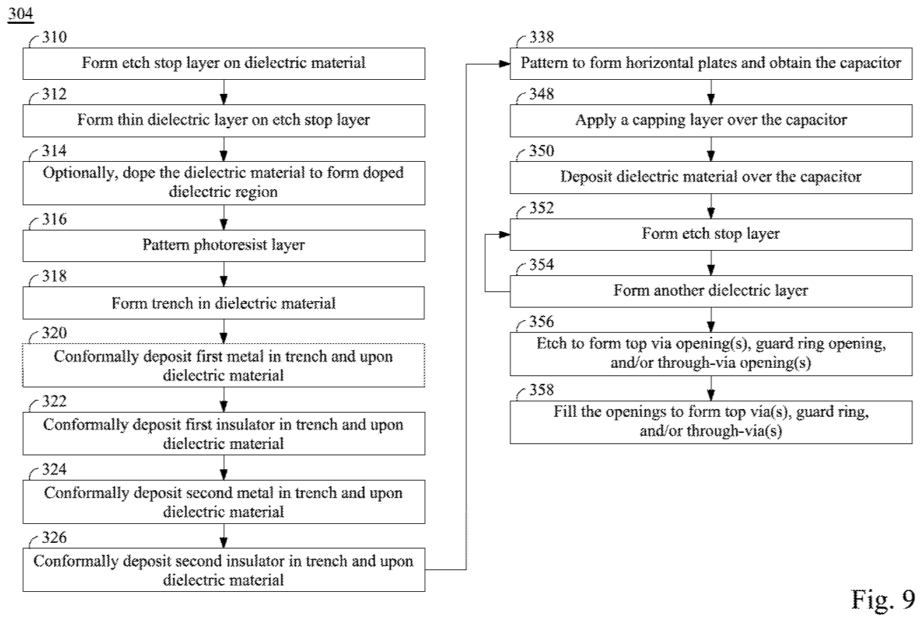

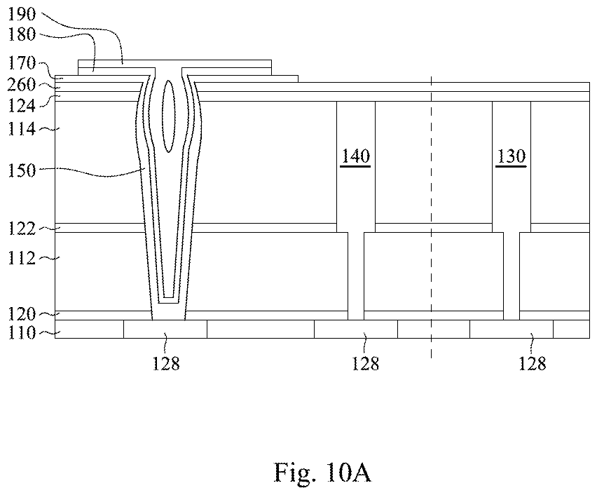

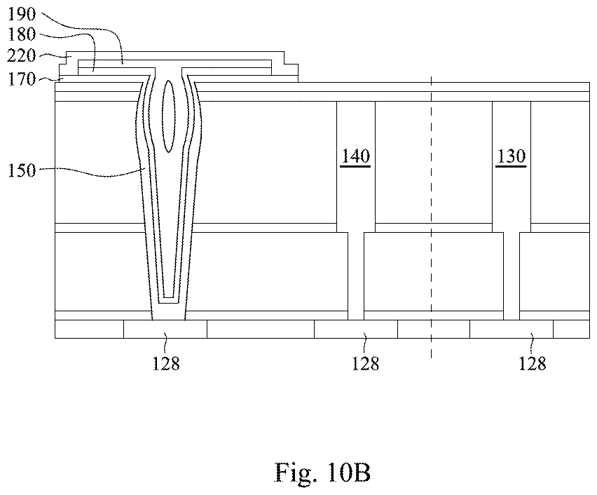

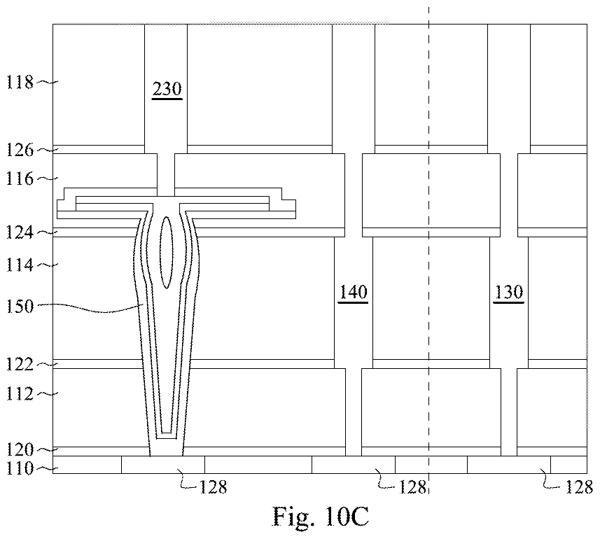

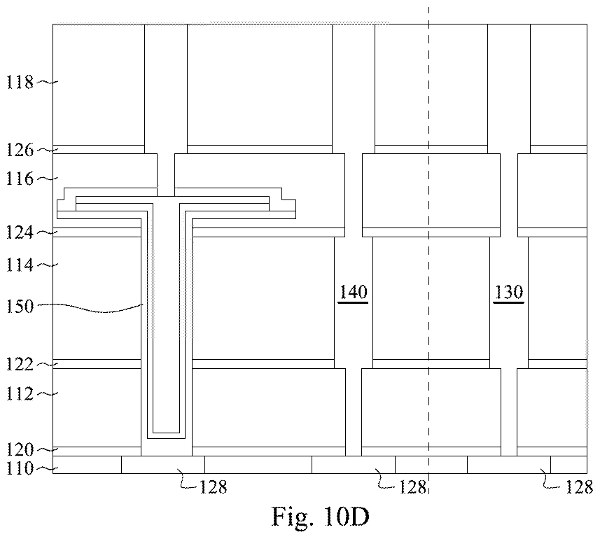

FIG. 9 is a third method 304 for making another interconnect structure, in accordance with some embodiments. This capacitor has a different structure. Some steps of the method are also illustrated in FIGS. 10A-10C.

Steps 310-326 of FIG. 9 are generally the same as FIG. 7. However, FIG. 9 differs after step 326 in that steps 328-336 are not performed. Instead, in step 338 of FIG. 9 and as illustrated in FIG. 10A, patterning is performed to form a first horizontal plate 170 from the first metal layer, a second horizontal plate 180 from the first insulator layer, and a third horizontal plate 190 from the second metal layer. The capacitor 150 is thus formed. Then, in step 348 of FIG. 9, a capping layer 220 is applied over the three horizontal plates. The resulting structure is illustrated in FIG. 10B. As seen here, the first horizontal plate 170 and the third horizontal plate 190 are both exposed from the top, although this is not always required.

This resulting structure is thus functionally identical to FIG. 3M. The following steps 350-358 of FIG. 9 are then identical to those of FIG. 7. FIG. 10C is a cross-sectional view of the final interconnect structure, which includes the capacitor 150 and a guard ring 140.

FIG. 10D is a Y-axis cross-sectional view of a variation of the capacitor, when optional doping step 314 is not performed, and so no bowed region is present in the capacitor 150. As a result, no void is present either. The guard ring 140 surrounds the capacitor, but is illustrated on only one side of the capacitor.

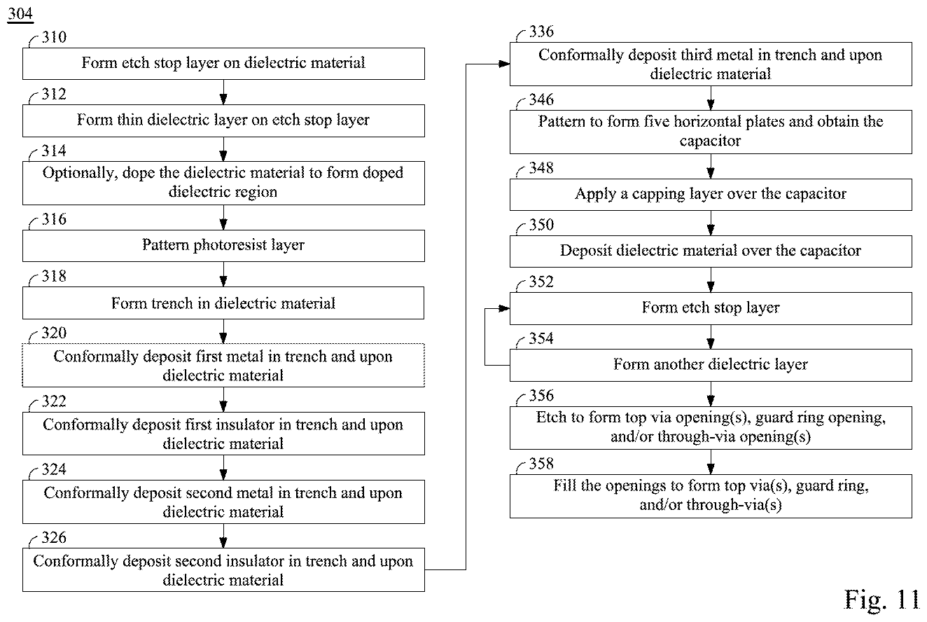

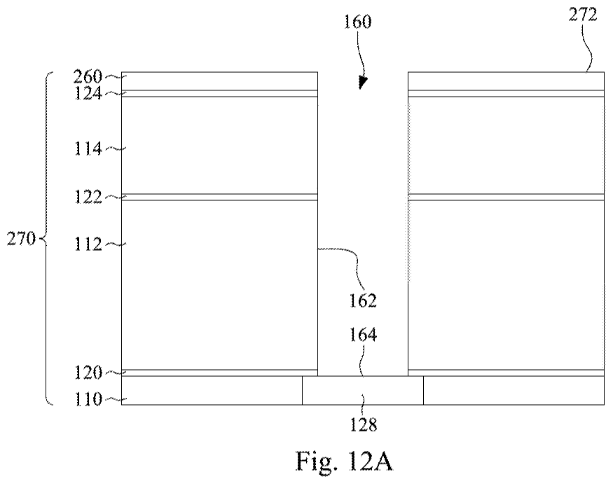

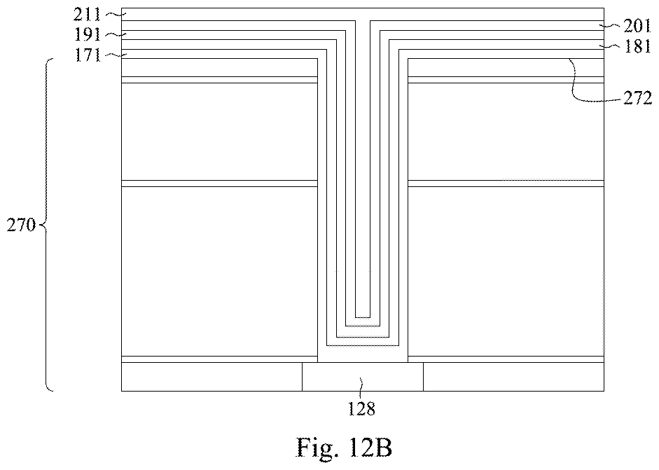

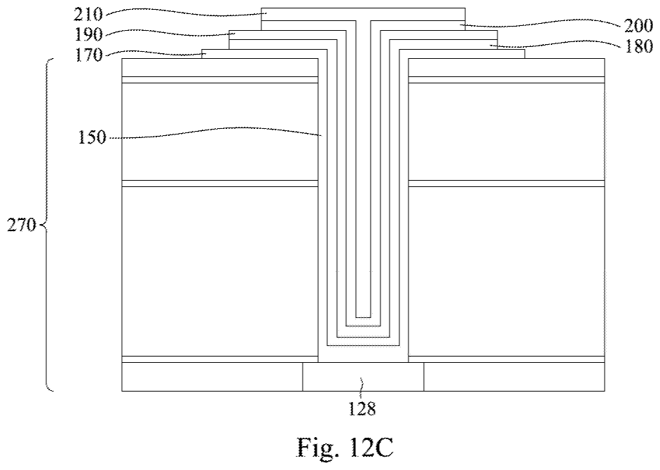

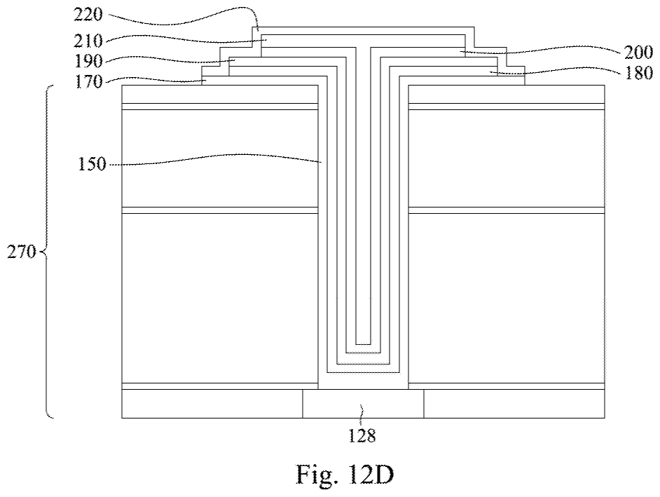

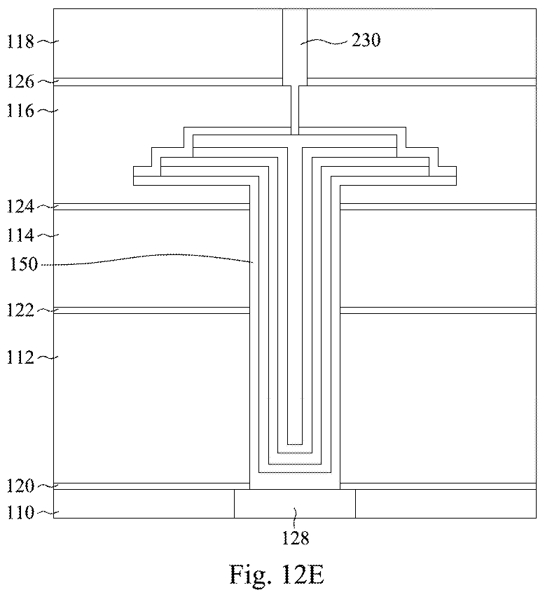

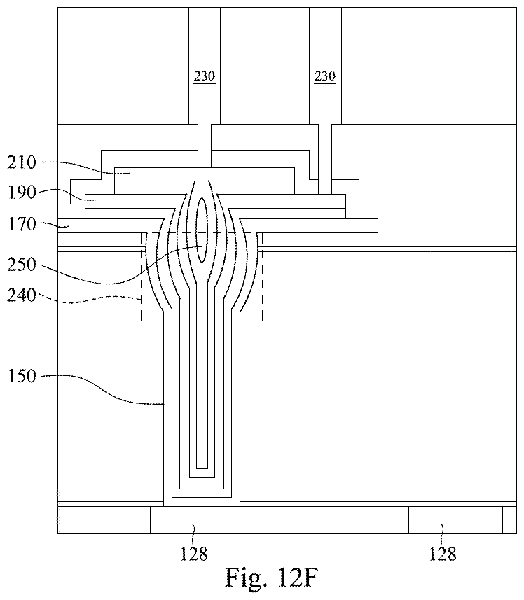

FIG. 11 is a fourth method 306 for making an interconnect structure, in accordance with some embodiments. The capacitor here has an MIMIM structure formed from five conformal layers. Some steps of the method are also illustrated in FIGS. 12A-12E.

Steps 310-318 of FIG. 11 are generally the same as FIG. 2. FIG. 12A shows the resulting structure after step 318, when a trench 160 for the capacitor has been formed in the dielectric material 270. The sidewalls 162 and the bottom surface 164 of the trench, along with the top surface 272 of the dielectric material, are labeled here.

In step 320 of FIG. 11, a first metal is deposited on the sidewalls 162 and the bottom surface 164 of the trench, as well as upon the surface of the dielectric material, in a conformal manner. This forms a first metal layer 171. Next, in step 322 of FIG. 11, a first insulator is deposited upon the first metal layer 171 on the sidewalls and the bottom surface of the trench, as well as upon the surface of the dielectric material, in a conformal manner. This forms a first insulator layer 181. Continuing, in step 324 of FIG. 11, a second metal is deposited upon the first insulator layer 181 on the sidewalls and the bottom surface of the trench, as well as upon the surface of the dielectric material, in a conformal manner. This forms a second metal layer 191. Then, in step 326 of FIG. 11, a second insulator is deposited upon the second metal layer 191 on the sidewalls and the bottom surface of the trench, as well as upon the surface of the dielectric material, in a conformal manner. This forms a second insulator layer 201. Finally, in step 336 of FIG. 11, a third metal is deposited upon the second insulator layer 201 on the sidewalls and the bottom surface of the trench, as well as upon the surface of the dielectric material, in a conformal manner. This forms a third metal layer 211. The resulting structure is shown in FIG. 12B. Portions of all five layers are present upon the top surface 272 of the dielectric structure. The conformal layers may be deposited using PVD, CVD, ALD, or other suitable process.

Continuing, in step 346 of FIG. 11 and as illustrated in FIG. 12C, patterning is performed to form a first horizontal plate 170 from the first metal layer, a second horizontal plate 180 from the first insulator layer, a third horizontal plate 190 from the second insulator layer, a fourth horizontal plate from the second insulator layer, and a fifth horizontal plate from the third metal layer. The capacitor 150 is thus formed. As seen here, the first horizontal plate 170, the third horizontal plate 190, and the fifth horizontal plate 210 (all three metal layers) are each exposed from the top. The second horizontal plate (insulator layer) is sized to isolate the first horizontal plate from the third horizontal plate. The fourth horizontal plate (insulator layer) is sized to isolate the third horizontal plate from the fifth horizontal plate. Generally, the fifth horizontal plate has the smallest width/length, and the first horizontal plate has the largest width/length.

Then, in step 348 of FIG. 11, a capping layer 220 is applied over the five horizontal plates. The resulting structure is illustrated in FIG. 12D. As seen here, the first horizontal plate 170 and the third horizontal plate 190 are both exposed from the top. Steps 350-358 of FIG. 11 are identical to those of FIG. 2. The resulting capacitor 150 is illustrated in FIG. 12E, with a top via 230 visible.

FIG. 12F is a Y-axis cross-sectional view of a variation of the MIMIM capacitor, where a bowed region 240 is present in the capacitor and a void 250 is present as well. This may be accomplished by shaping the trench using a doped dielectric region 242, which is indicated as optional step 314 in the method of FIG. 11. It is noted that in this illustration, the void 250 is present within the third metal layer, rather than the second metal layer as in FIG. 1A. In addition, the void extends above the first horizontal plate 170, and is not entirely within the trench. Two top vias 230 are illustrated here, contacting the third horizontal plate 190 and the fifth horizontal plate 210. The first horizontal plate 170 contacts the inter-metal contact 128.

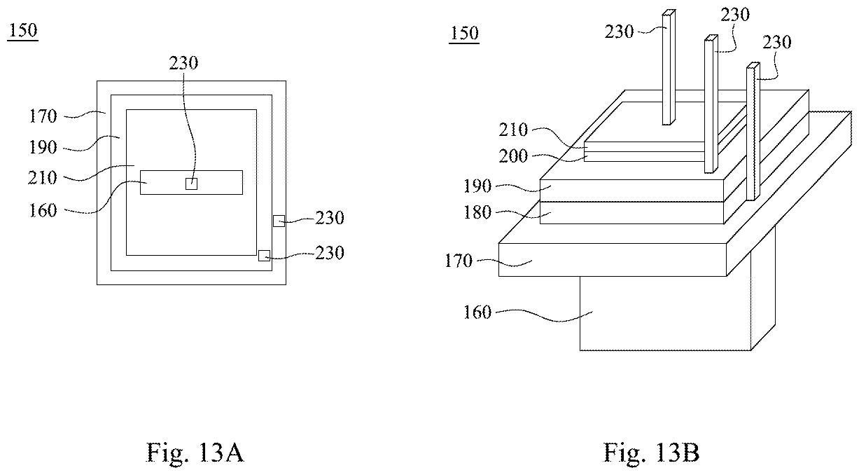

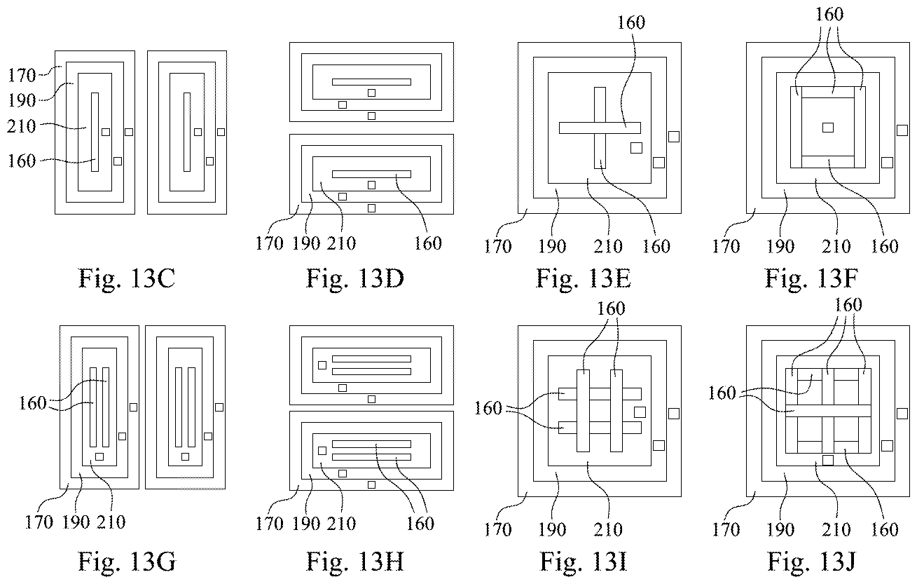

FIG. 13A is a plan view of one arrangement of the trench and horizontal plates of the capacitor. Dotted line A-A indicates the plan through which FIG. 12E can be taken. In FIG. 13A, the capping layer is not shown. All three metal horizontal plates 170, 190, 210 are visible and exposed from the top. Again, the trench 160 is shown as a rectangle and extends downward into the page. Three top vias 230 are illustrated, one top via contacting each metal horizontal plate. FIG. 13B is a perspective view of the capacitor of FIG. 13A. Here, the two insulator horizontal plates 180, 200 are visible.

FIGS. 13C-13J are various plan views of the capacitor in accordance with some embodiments, showing different shapes and arrangements of the trench and horizontal plates of capacitor(s) which can be used to optimize the density and capacitance for various applications. About the same surface area is used in each figure, and these are merely illustrative non-limiting examples. Each figure is similar to its corresponding figure in FIGS. 4C-4J, except the capacitor has three metal horizontal plates, and three top vias are illustrated in various locations.

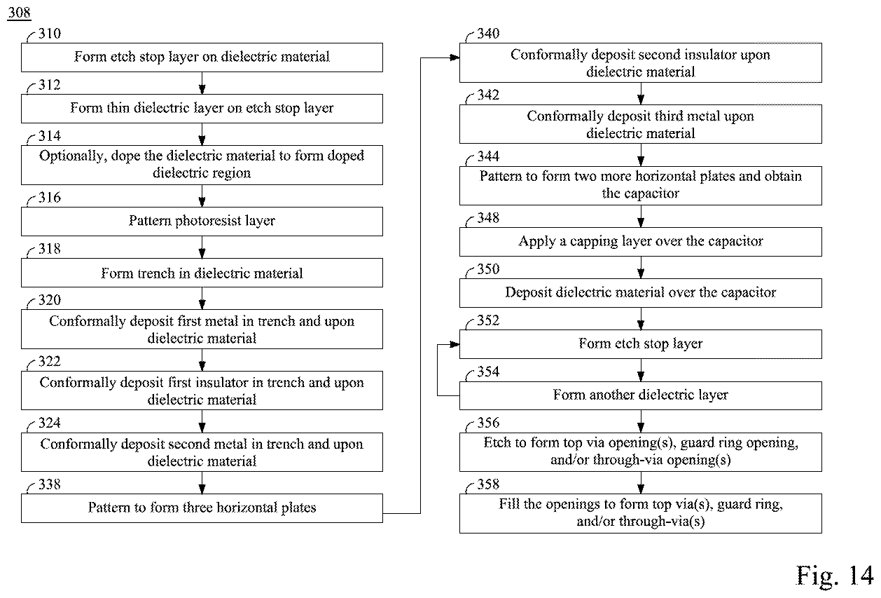

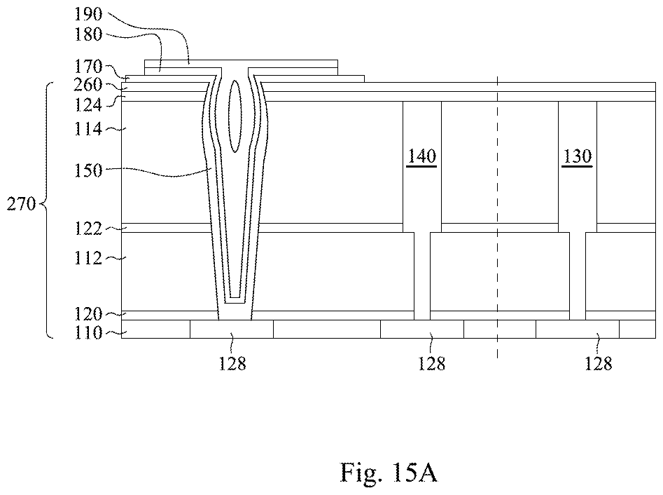

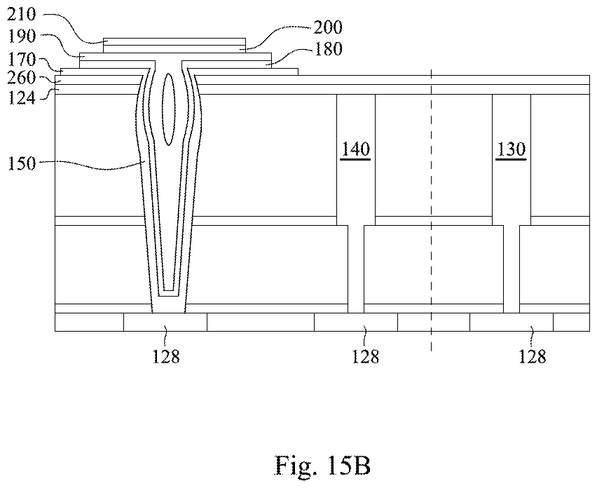

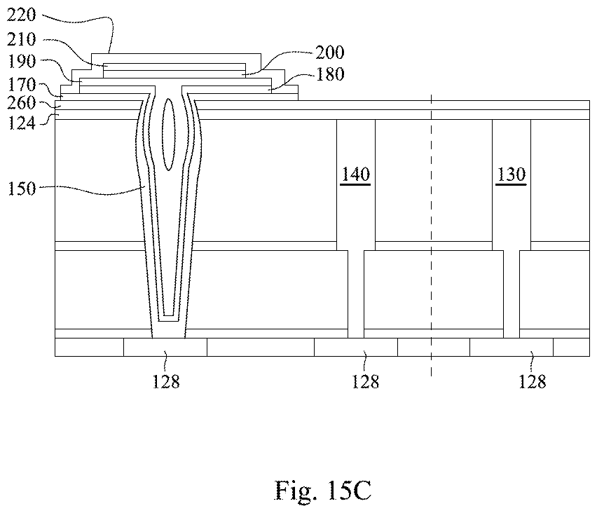

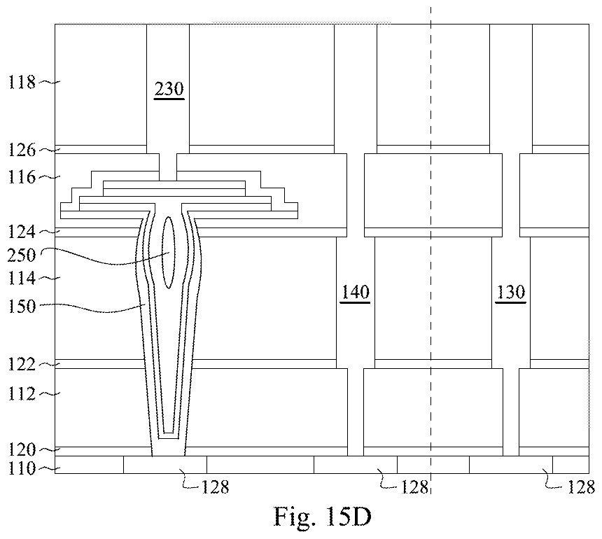

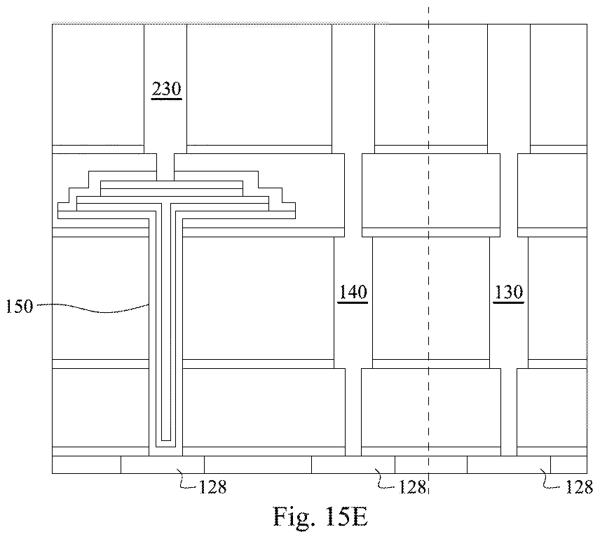

FIG. 14 is a fifth method 308 for making an interconnect structure, in accordance with some embodiments. The capacitor has an MIMIM structure with five horizontal plates. Some steps of the method are also illustrated in FIGS. 15A-15D.

Steps 310-324 of FIG. 14 are generally the same as the method of FIG. 9. After step 324, step 338 is performed. FIG. 15A shows the resulting structure after step 338 of FIG. 14. Patterning has been performed to form a first horizontal plate 170 from the first metal layer, a second horizontal plate 180 from the first insulator layer, and a third horizontal plate 190 from the second metal layer.

Continuing, in step 340 of FIG. 14, a second insulator layer is conformally deposited upon the dielectric material. In step 342 of FIG. 14, a third metal layer is conformally deposited upon the dielectric material. Then, in step 344 of FIG. 14, patterning is performed to form a fourth horizontal plate 200 from the second insulator layer, and a fifth horizontal plate 210 from the third metal layer.

The resulting structure is shown in FIG. 15B. Again, the first horizontal plate 170, the third horizontal plate 190, and the fifth horizontal plate 210 (all three metal layers) are each exposed from the top. The second horizontal plate (insulator layer) is sized to isolate the first horizontal plate from the third horizontal plate. The fourth horizontal plate (insulator layer) is sized to isolate the third horizontal plate from the fifth horizontal plate. Generally, the fifth horizontal plate has the smallest width/length, and the first horizontal plate has the largest width/length.

Then, in step 348 of FIG. 14, a capping layer is applied over the five horizontal plates. The resulting structure is illustrated in FIG. 15C. Steps 350-358 of FIG. 14 are identical to those of FIG. 9. The resulting capacitor 150 is illustrated in FIG. 15D, with a top via 230 visible. The capacitor includes a void 250.

FIG. 15E is a Y-axis cross-sectional view of a variation of the capacitor, where no bowed region or void is present in the capacitor 150. The guard ring 140 surrounds the capacitor, but is illustrated on only one side of the capacitor.

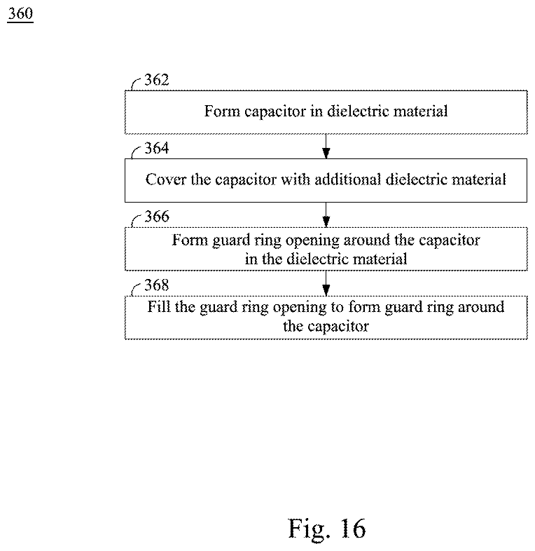

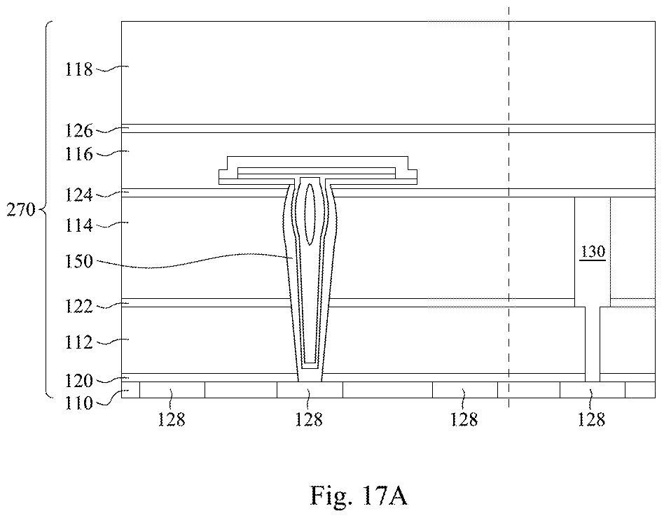

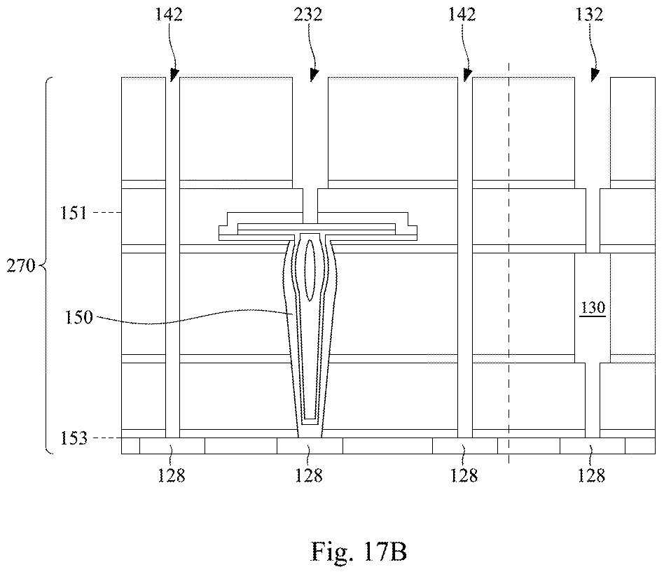

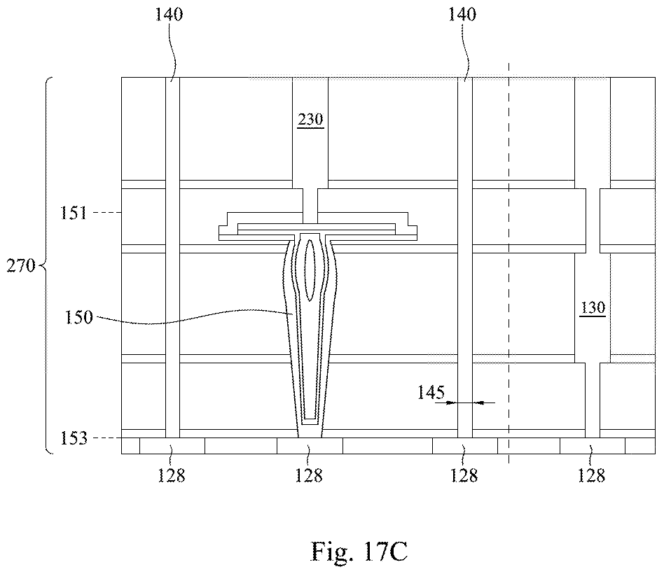

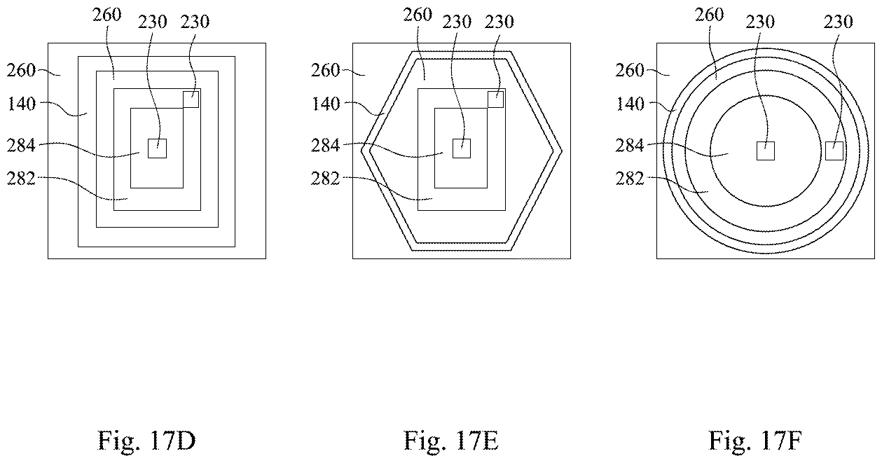

FIG. 16 is a method 360 for making an interconnect structure in which a guard ring is formed around a capacitor, in accordance with some embodiments. Some steps of the method are also illustrated in FIGS. 17A-17C.

In step 362 of FIG. 16, a capacitor is formed in a dielectric material. In step 364 of FIG. 16, the capacitor is covered with additional dielectric material. Additional steps for making the capacitor can be seen, for example, in FIGS. 2, 7, 9, 11, and 14. FIG. 17A is a cross-sectional view of the resulting interconnect structure. The structure in this state is similar to that shown in FIG. 3O, except there is no partial guard ring structure as seen there. A capacitor 150 is present, as well as a partial through-via 130.

Next, in step 366 of FIG. 16 and as illustrated in FIG. 17B, a guard ring opening 142 is formed around the capacitor 150 in the dielectric material 270. The guard ring opening passes through the dielectric structure 270, and extends at least from the top level 151 of the capacitor to the bottom level 513 of the capacitor. A top via opening 232 and a through-via opening 132 are also illustrated as being formed in the same step.

Then, in step 368 of FIG. 16 and as illustrated in FIG. 17C, the guard ring opening is filled with a metal to form a guard ring 140 around the capacitor. The top via opening and the through-via opening are also filled to form a top via 230 and a through-via 130. In FIG. 17C, the guard ring 140 is illustrated as having a constant width 145 from the top level 151 to the bottom level 153, in contrast to the guard ring 140 of FIG. 1A, which had a varying width along its depth. In particular embodiments, the guard ring 140 has a minimum width 145 of about 0.5 micrometers, to effectively reduce noise. While the width of the guard ring may vary along its height, it never decreases below about 0.5 micrometers.

In addition, the guard ring is completely formed in one fill step rather than multiple fill steps as in the method of FIG. 2. It is noted that no electrical current or signal passes through the guard ring, and so no electrical contacts are made to the guard ring.

FIGS. 17D-17F are various plan views of the interconnect structure, showing different shapes and arrangements of the capacitor and the guard ring which could be used as desired, depending on the application. The dielectric material 260 has the same surface area in each figure, and these are merely illustrative non-limiting examples. Each figure includes the guard ring 140, the CBM 282, the CTM 284, and two top vias 230 contacting the CBM and the CTM. In FIG. 17D, the guard ring 140 has a rectangular shape, and the capacitor 150 also has a rectangular shape. In FIG. 17E, the guard ring 140 has a hexagonal shape, while the capacitor 150 has a rectangular shape. In FIG. 17D, the guard ring 140 and the capacitor 150 each have a circular shape.

Semiconductor packages with the interconnect structure containing the capacitors illustrated herein and/or the guard ring surrounding the capacitor may be used in various applications. Those semiconductor packages might be used in various applications such as image signal processors (ISP), which can be combined with CMOS image sensors; or global shutters for high speed capture in a camera or monitor. Other potential applications might include BCD (Bipolar-CMOS-DMOS) circuits for driving discrete high voltage components; drivers for LCD, OLED, AMOLED, or QLED display panels; image sensors that can be used in systems such as mobile telephones, facial recognition systems, or as motion sensors for automotive applications, security applications, energy efficiency, etc.; power management devices that control the flow and direction of electrical power; and/or artificial intelligence applications.

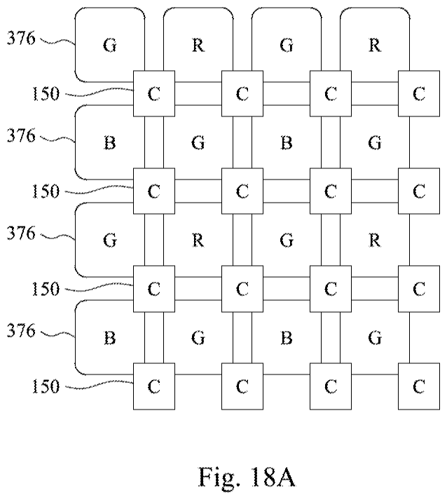

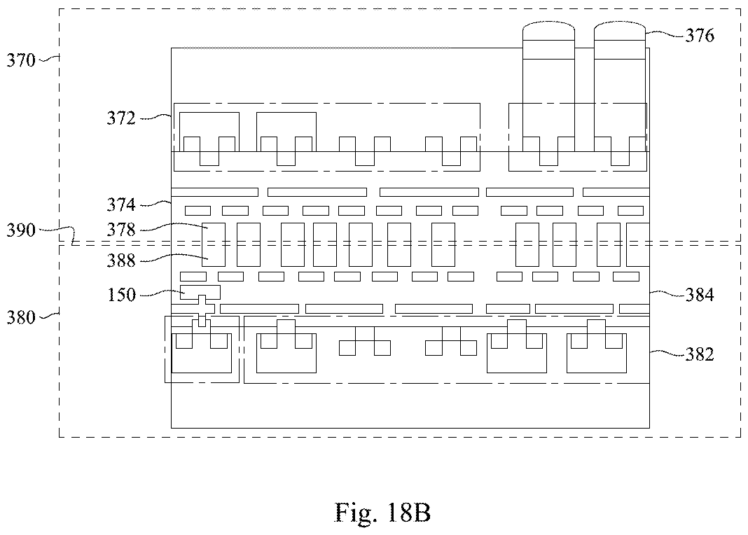

FIG. 18A is a plan view schematic diagram of a capacitor array used in a CMOS image sensor, in accordance with some embodiments. As illustrated here, the CMOS image sensor includes an array of photosensors 376 that convert light into an electrical signal. A color filter array is used to filter the light by wavelength range to obtain information about the light intensity. As illustrated here, a Bayer filter is used with two green elements, one red element, and one blue element (Indicated as R, G, or B). A capacitor 150 is electrically connected to each photosensor in a 1:1 ratio.

FIG. 18B is a cross-sectional view of a CMOS image sensor (CIS) semiconductor package 370 which is connected to an image signal processor (ISP) semiconductor package 380. The front side of the CIS semiconductor package includes photosensors 376 on the right-hand side. Transistors 372 on the left-hand side are used for control. An interconnect structure 374 is present on the back side of the CIS semiconductor package. The ISP semiconductor package includes transistors 382 and an interconnect structure 384. Capacitor(s) 150 of the present disclosure are present in the interconnect structure. The CIS semiconductor package 370 and the ISP semiconductor package 380 are connected to each other through hybrid bonds 390 that use both a dielectric bond and a metal bond. Metal bond pads 378, 388 are present in each package.

The capacitors and the guard ring described herein have several advantages, whether used separately or together. The various capacitors can be implemented with many different geometries and mixed as needed, providing flexibility in trench design. The designs are compatible with logic processes, and have robust reliability. The topography of the capacitor can also be better controlled. The use of deep trenches can increase the capacitance per unit area by up to 4 times more than a traditional structure. This may permit large amounts of image data to be processed at one time. Deep trenches can also release stress which may arise due to, for example, the differences in the coefficient of expansion between different layers or due to the heterogeneous distribution of material within layers. The presence of a bowed region can also provide stress relief, the second insulator (for example, an air void) allows the capacitor to bend in response to stresses while still functioning as a capacitor. The use of the guard ring increases reliability of the capacitor and reduces noise which can damage the capacitor. Such noise may result from the surrounding interconnect structure or the layers above and below the capacitor, and which can create electrical effects that damage the capacitor.

The present disclosure thus relates in some embodiments to various methods for making a capacitor. A trench is formed in a dielectric material. A first metal is deposited on sidewalls and a bottom surface of the trench, and upon a surface of the dielectric material to form a first metal layer. A first insulator is deposited upon the first metal layer on the sidewalls and the bottom surface of the trench, and upon the surface of the dielectric material to form a first insulator layer. A second metal layer is deposited upon the first insulator layer on sidewalls and the bottom surface of the trench, over a second insulator in the trench, and upon the surface of the dielectric material to form a second metal layer. Portions of the second metal layer and the first insulator layer upon the surface of the dielectric material are removed, for example by planarization. A primary insulator is applied upon the surface of the dielectric material to isolate the second metal in the trench. A third metal layer is formed upon the first insulator layer upon the surface of the dielectric material. Patterning is done to form a first horizontal plate from the first metal layer, a second horizontal plate from the first insulator layer, and a third horizontal plate from the third metal layer to obtain the capacitor.

The methods may further comprise applying a capping layer over the first horizontal plate, the second horizontal plate, and the third horizontal plate. In some further embodiments, the methods may further comprise doping the dielectric material to form a doped dielectric region prior to forming the trench in the dielectric material, such that the trench is formed with a bowed region. The second insulator can be located within the bowed region. The depth of the bowed region may be from about 10% to about 50% of a depth of the trench.

In other embodiments, the methods may further comprise: forming top via openings to the first horizontal plate and the third horizontal plate and a guard ring opening that surrounds the capacitor; and filling the top via openings and the guard ring opening to form top vias and a guard ring.

In some embodiments, the second insulator in the trench is air or silicon nitride (SiN), The dielectric material may be part of an interconnect structure.

In some specific embodiments, the methods may further comprise after depositing the second metal layer, depositing the second insulator into the trench. Then, after planarizing to remove portions of the second metal layer and the first insulator layer, the second insulator is etched to form a recess. The recess is then refilled with the second metal so the second metal layer is over the second insulator.

In particular embodiments, the second horizontal plate exposes a perimeter of the first horizontal plate. In other embodiments, the trench has an aspect ratio of about 3 to about 15. In yet additional embodiments, the trench may pass through an etch stop layer.

Also disclosed herein are capacitors, comprising: a vertical trench in which a first metal, a first insulator, and a second metal are arranged; a first horizontal plate above the vertical trench which is connected to the first metal in the vertical trench; a second horizontal plate above the first horizontal plate which is connected to the first insulator in the vertical trench; and a third horizontal plate above the second horizontal plate made of a third metal.

In some embodiments, the second horizontal plate isolates the second metal from the third horizontal plate. In other embodiments, the third metal and the second metal are the same, and the third horizontal plate is connected to the second metal in the vertical trench. In still further embodiments, a second insulator is also present in the trench.

The capacitor can, in additional embodiments, further comprise: a fourth horizontal plate above the third horizontal plate made of a second insulator; and a fifth horizontal plate above the fourth horizontal plate made of a fourth metal.

Also disclosed herein are semiconductor devices with an interconnect structure that includes a capacitor, wherein the capacitor has one of the structures described above. In particular embodiments, the semiconductor device is an image signal processor, and the capacitor is electrically connected to a photodiode.

Also disclosed herein are capacitors with a bowed region, comprising: a vertical trench with a bowed region in which a first metal, a first insulator, a second metal, and a second insulator are arranged, wherein the second insulator is encapsulated or surrounded by the second metal.

In some further embodiments, the capacitor further comprises: a first horizontal plate above the vertical trench which is connected to the first metal in the vertical trench; a second horizontal plate above the first horizontal plate which is connected to the first insulator in the vertical trench; and a third horizontal plate above the second horizontal plate made of a third metal. In some embodiments, the second horizontal plate isolates the second metal from the third horizontal plate. In other embodiments, the third metal and the second metal are the same, and the third horizontal plate is connected to the second metal in the vertical trench.

Also disclosed herein are methods for making a capacitor with a bowed region. A dielectric material is doped to form a doped dielectric region. A photoresist layer is patterned above the dielectric material that exposes the doped dielectric region. The dielectric material and the doped dielectric region are then etched to form a trench with a bowed region. A first metal is conformally deposited on sidewalls and a bottom surface of the trench, and upon a surface of the dielectric material to form a first metal layer. A first insulator is conformally deposited upon the first metal layer on the sidewalls and the bottom surface of the trench, and upon the surface of the dielectric material to form a first insulator layer. A second metal is conformally deposited upon the first insulator layer on sidewalls and the bottom surface of the trench, and upon the surface of the dielectric material to form a second metal layer. The capacitor is thus obtained.

In some further embodiments, after conformally depositing the second metal layer, a second insulator is deposited into the trench. The second insulator is then covered with the second metal.

Also disclosed herein are semiconductor devices comprising a capacitor with a bowed region.

Also disclosed in various embodiments are capacitors that comprise a vertical trench in which a first metal, a first insulator, a second metal, and a second insulator are annularly arranged. A first horizontal plate is present above the vertical trench which is connected to the first metal in the vertical trench. A second horizontal plate is present above the first metal horizontal plate which is connected to the first insulator in the vertical trench. A third horizontal plate is present above the second horizontal plate which is connected to the second metal in the vertical trench. A capping layer may be present if desired to cover the first horizontal plate, the second horizontal plate, and the third horizontal plate.

Also disclosed are alternative methods for making a capacitor. A trench is formed in a dielectric material. A first metal is conformally deposited on sidewalls and a bottom surface of the trench, and upon a surface of the dielectric material to form a first metal layer. A first insulator is conformally deposited upon the first metal layer on the sidewalls and the bottom surface of the trench, and upon the surface of the dielectric material to form a first insulator layer. A second metal is conformally deposited upon the first insulator layer on sidewalls and the bottom surface of the trench, and upon the surface of the dielectric material to form a second metal layer, wherein the second metal layer surrounds an air void. Patterning is then done to form a first horizontal plate from the first metal layer, a second horizontal plate from the first insulator layer, and a third horizontal plate from the second metal layer. Also disclosed herein are semiconductor devices comprising a capacitor of this structure.

The present disclosure also relates to interconnect structures for an integrated circuit, comprising a capacitor in a dielectric material and a guard ring surrounding the capacitor.

Also disclosed are methods of making an interconnect structure for an integrated circuit, comprising: forming a trench and a guard ring opening around the trench in a dielectric material; forming a capacitor in the trench and upon a surface of the dielectric material; and filling the guard ring opening with a metal to form a guard ring around the capacitor.

Also disclosed are semiconductor devices that comprise: a capacitor in a dielectric material; and a guard ring surrounding the capacitor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for making a capacitor, comprising:
forming a trench in a dielectric material;
depositing a first metal on sidewalls and a bottom surface of the trench, and upon a surface of the dielectric material to form a first metal layer;
depositing a first insulator upon the first metal layer on the sidewalls and the bottom surface of the trench, and upon the surface of the dielectric material to form a first insulator layer;
depositing a second metal upon the first insulator layer on sidewalls and the bottom surface of the trench, over a second insulator in the trench, and upon the surface of the dielectric material to form a second metal layer;
planarizing to removing portions of the second metal layer and the first insulator layer upon the surface of the dielectric material;
applying a primary insulator upon the surface of the dielectric material to isolate the second metal in the trench;
forming a third metal layer upon the first insulator layer upon the surface of the dielectric material; and
patterning to form a first horizontal plate from the first metal layer, a second horizontal plate from the first insulator layer, and a third horizontal plate from the third metal layer to obtain the capacitor.

2. The method of claim 1, further comprising applying a capping layer over the first horizontal plate, the second horizontal plate, and the third horizontal plate.

3. The method of claim 1, further comprising doping the dielectric material to form a doped dielectric region prior to forming the trench in the dielectric material, such that the trench is formed with a bowed region.

4. The method of claim 3, wherein the second insulator is located within the bowed region.

5. The method of claim 3, wherein a depth of the bowed region is from about 10% to about 50% of a depth of the trench.

6. The method of claim 1, further comprising:
forming top via openings to the first horizontal plate and the third horizontal plate and a guard ring opening that surrounds the capacitor; and
filling the top via openings and the guard ring opening to form top vias and a guard ring.

7. The method of claim 1, wherein the second insulator in the trench is air or silicon nitride (SiN).

8. The method of claim 1, further comprising:
after conformally depositing the second metal layer, depositing the second insulator into the trench; and
after planarizing to remove portions of the second metal layer and the first insulator layer, etching the second insulator to form a recess; and
refilling the recess with the second metal so the second metal layer is over the second insulator.

9. The method of claim 1, wherein the dielectric material is part of an interconnect structure.

10. The method of claim 1, wherein the second horizontal plate exposes a perimeter of the first horizontal plate.

11. The method of claim 1, wherein the trench has an aspect ratio of about 3 to about 15.

12. The method of claim 1, wherein the trench passes through an etch stop layer.

13. A capacitor, comprising:
a vertical trench in which a first metal, a first insulator, and a second metal are arranged;
a first horizontal plate above the vertical trench which is connected to the first metal in the vertical trench;
a second horizontal plate above the first horizontal plate which is connected to the first insulator in the vertical trench; and
a third horizontal plate above the second horizontal plate made of a third metal.

14. The capacitor of claim 13, further comprising a capping layer covering the first horizontal plate, the second horizontal plate, and the third horizontal plate.

15. The capacitor of claim 13, further comprising a second insulator in the trench.

16. The capacitor of claim 13, wherein the second horizontal plate isolates the second metal from the third horizontal plate.

17. The capacitor of claim 13, wherein the third metal and the second metal are the same, and the third horizontal plate is connected to the second metal in the vertical trench.

18. The capacitor of claim 13, further comprising:
a fourth horizontal plate above the third horizontal plate made of a second insulator; and
a fifth horizontal plate above the fourth horizontal plate made of a fourth metal.

19. A semiconductor device with an interconnect structure that includes a capacitor, wherein the capacitor comprises:
a vertical trench in which a first metal, a first insulator, a second metal, and a second insulator are arranged;
a first horizontal plate above the vertical trench which is connected to the first metal in the vertical trench;
a second horizontal plate above the first horizontal plate which is connected to the first insulator in the vertical trench; and
a third horizontal plate above the second horizontal plate made of a third metal.

20. The semiconductor device of claim 19, wherein the semiconductor device is an image signal processor, and the capacitor is electrically connected to a photodiode.
